(19) United States
(12) Patent Application Publication
(10) Pub. No.: US 2021/0398936 A1
(43) Pub. Date: Dec. 23, 2021

(54) LASER BONDED DEVICES, LASER BONDING TOOLS, AND RELATED METHODS

(71) Applicant: Amkor Technology Singapore Holding Pte. Ltd., Singapore (SG)

(72) Inventors: Dong Hyeon Park, Seoul (KR); Min Ho Kim, Seoul (KR); Dong Su Ryu, Incheon (KR); Seok Ho Na, Incheon (KR); Choong Hoe Kim, Seoul (KR); Yun Seok Song, Gwangju (KR); Woo Kyung Ju, Gyeonggi-do (KR)

(73) Assignee: Amkor Technology Singapore Holding Pte. Ltd., Singapore (SG)

(21) Appl. No.: 17/244,463

(22) Filed: Apr. 29, 2021

Related U.S. Application Data
(63) Continuation-in-part of application No. 16/908,928, filed on Jun. 23, 2020.

(51) Int. Cl. H01L 23/00; B23K 26/18; B23K 1/005

(52) U.S. Cl. CPC H01L 24/75; B23K 26/18; B23K 1/0056; B23K 2103/56; H01L 2224/75901; H01L 2224/7598; H01L 2224/75262

(57) ABSTRACT

In one example, a system can comprise a laser assisted bonding (LAB) tool comprising a stage block and a laser source facing the stage block. The stage block can be configured to support a first substrate and a first electronic component coupled with the first substrate, the first electronic component comprising a first interconnect. The laser source can be configured to emit a first laser towards the stage block to induce a first heat on the first interconnect to bond the first interconnect with the first substrate. Other examples and related methods are also disclosed herein.

### CROSS-REFERENCE TO RELATED APPLICATIONS & INCORPORATION BY REFERENCE

This application is a continuation-in-part of U.S. patent application Ser. No. 16/908,928, filed on Jun. 23, 2020 (pending), and titled “Hybrid Bonding Interconnection Using Laser And Thermal Compression”, the entire contents of which are hereby incorporated herein by reference.

Various aspects of this application are related to U.S. patent application Ser. No. 17/005,021, filed Aug. 27, 2020, and titled “System And Method For Laser Assisted Bonding Of An Electronic Device” and published as US 2021/0082717 A1, the entire contents of which are hereby incorporated herein by reference.

### TECHNICAL FIELD

The present disclosure relates, in general, to electronic devices, and more particularly, to bonder tools and methods for bonding semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A to 1C show cross-sectional views of an example semiconductor device.

FIGS. 2A to 2B show cross-sectional views of an example bonder tool for bonding an example semiconductor device.

FIGS. 3A to 3C show cross-sectional views of an example method for bonding an example semiconductor device.

FIGS. 4A to 4C show cross-sectional views of an example method for bonding an example semiconductor device.

FIGS. 5A to 5C show cross-sectional views of an example method for bonding an example semiconductor device.

FIGS. 6A to 6D show detailed cross-sectional views of example bonding stages for example semiconductor devices using a bonder tool.

FIGS. 7A to 7C show cross-sectional views and plan views of example bonding stages for example semiconductor devices using a bonder tool.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” “including,” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

### DESCRIPTION

In one example, a method to manufacture a semiconductor device comprises providing an electronic component over a substrate, wherein an interconnect of the electronic component contacts a conductive structure of the substrate, providing the substrate over a laser assisted bonding (LAB) tool, wherein the LAB tool comprises a stage block with a window, and heating the interconnect with a laser beam through the window until the interconnect is bonded with the conductive structure.

In another example, a method to manufacture a semiconductor device comprises providing an electronic component over a first substrate side of a substrate, wherein an interconnect of the electronic component contacts a conductive structure of the substrate, providing the substrate in a hybrid bonder tool comprising a laser assisted boding (LAB) tool and a thermal/compression boding (TCB) tool, applying a first heat to the interconnect with a laser beam from the LAB tool through a second substrate side opposite the first substrate side, and applying a second heat or compression to the interconnect with the TCB tool through the electronic component.

In a further example, a system comprises a laser assisted bonding (LAB) tool comprises a laser source, a stage block with a window over the laser source, wherein the laser source is configured to emit a laser beam through the window to apply a first heat on an interconnect of a workpiece supported by the stage block.

In one example, a system can comprise a laser assisted bonding (LAB) tool comprising a stage block and a laser source facing the stage block. The stage block can be configured to support a first substrate and a first electronic component coupled with the first substrate, the first electronic component comprising a first interconnect. The laser source can be configured to emit a first laser towards the stage block to induce a first heat on the first interconnect to bond the first interconnect with the first substrate.

In one example, a semiconductor device can comprise a substrate comprising a substrate top side and a substrate bottom side, and a first electronic component comprising a first interconnect bonded to the substrate top side by a first laser beam emitted towards the substrate bottom side.

Other examples are included in the present disclosure. Such examples may be found in the figures, in the claims, or in the description of the present disclosure.

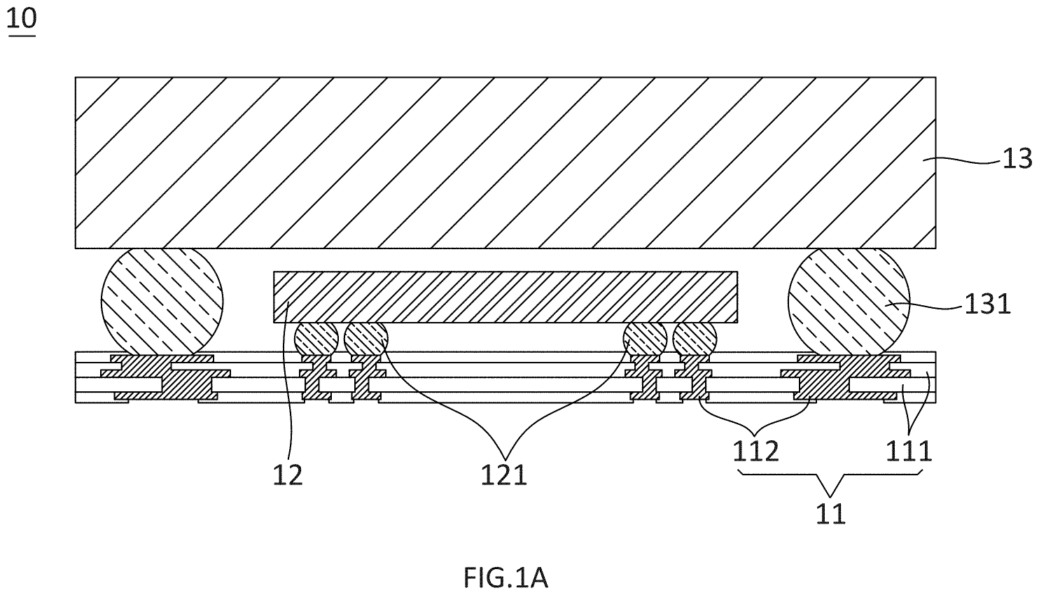

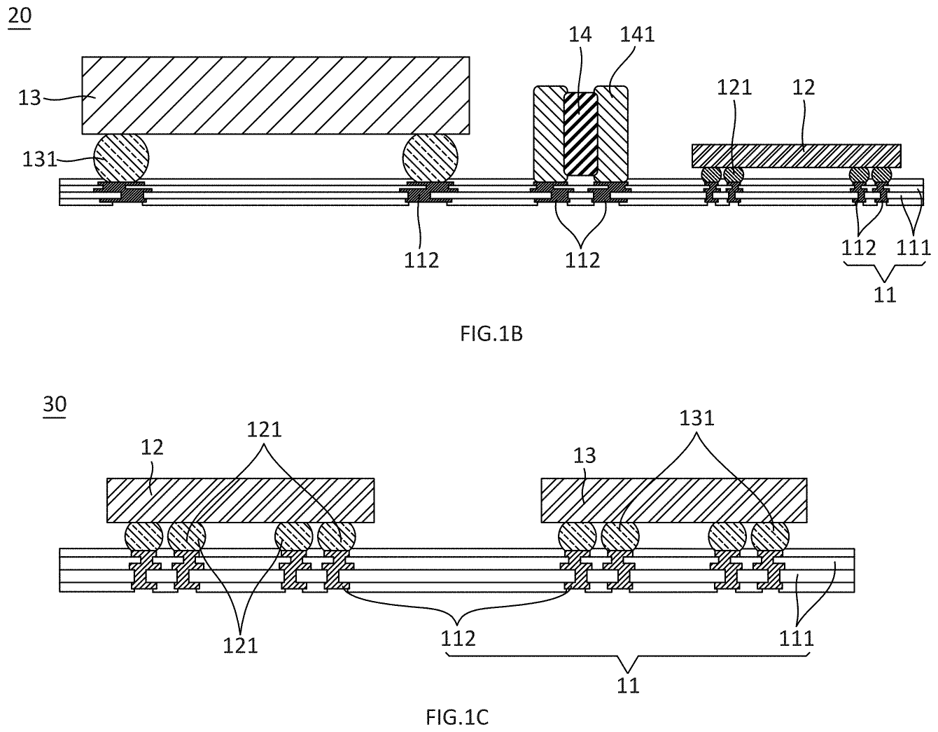

FIG. 1A shows a cross-sectional view of an example semiconductor device 10. In the example shown in FIG. 1A, semiconductor device 10 can comprise substrate 11, electronic components 12 or 13, and interconnects 121 or 131. Substrate 11 can comprise dielectric structure 111 and conductive structure 112. Substrate 11 and interconnects 121 or 131 can provide electrical coupling between an external component and electronic components 12 or 13. In some examples, at least one of electronic component 12 or electronic component 13 can comprise mold compound or a molded package comprising mold compound. In such examples, the mold compound or molded package optionally can include one of electronic component 12 or electronic component 13 located inside, on, or under the mold compound or molded package.

FIG. 1B shows a cross-sectional view of an example semiconductor device 20. In the example shown in FIG. 1B, semiconductor device 20 can comprise substrate 11, electronic components 12, 13, or 14, and interconnects 121 or 131. Substrate 11 and electronic components 12 or 13 can be similar to substrate 11 and electronic components 12 or 13 shown in FIG. 1A. Electronic component 14 can comprise interconnect 141.

FIG. 1C shows a cross-sectional view of an example semiconductor device 30. In the example shown in FIG. 1C, semiconductor device 30 can comprise substrate 11, electronic component 12, and interconnects 121. Substrate 11 and electronic component 12 can be similar to substrate 11 and electronic components 12 or 13 shown in FIG. 1A. Also, electronic component 12 can be longer or thinner than electronic components 12 or 13 shown in FIG. 1A.

In some examples, substrate 11 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can referred to as a printed circuit board (PCB) or a laminate substrate. Such pre-formed substrate can be formed through a semi-additive or modified-semi-additive process.

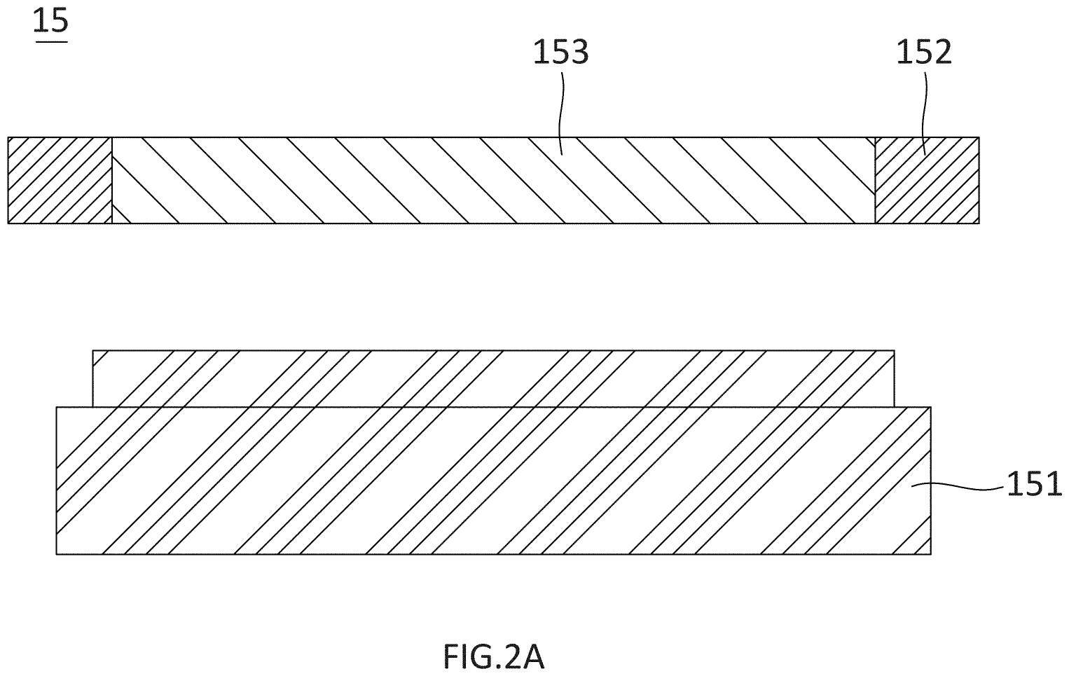

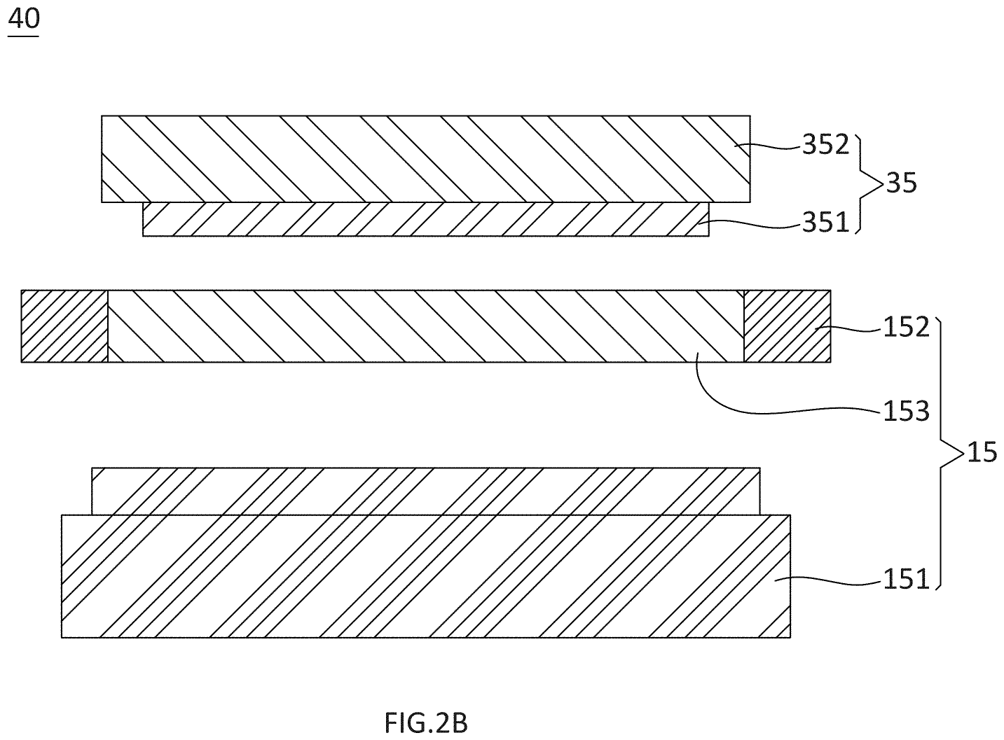

In some examples, substrate 11 can be a re-distribution layer (“RDL”) substrate. In some examples, RDL substrates can comprise one or more conductive redistribution layers and one or more dielectric layers that can be formed layer by layer over an electronic device to which the RDL substrate is to be electrically coupled. In some examples, RDL substrates can comprise one or more conductive redistribution layers and one or more dielectric layers that can be formed layer by layer over a carrier that can be entirely removed or at least partially removed after the electronic device and the RDL substrate are coupled together. In some examples, window 153 shown in FIG. 2A can comprise or can be a portion of such carrier. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as an electroplating process or an electroless plating process. The conductive patterns can comprise an electrically conductive material such as copper or other plateable metal. The locations of the conductive patterns can be made using a photo-patterning process, for example a photolithography process and a photoresist material to form a photolithographic mask. The dielectric layers of the RDL substrate can be patterned with a photo-patterning process, which can include a photolithographic mask through which light is exposed at photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si3N4), silicon oxide (SiO₂), or silicon oxynitride (SiON). The inorganic dielectric layer or layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Other substrates in this disclosure can also comprise an RDL substrate.

It should be noted that various semiconductor devices 10, 20, or 30 described herein are for the understanding of the present disclosure and that various other semiconductor devices can be used in the present disclosure. The present disclosure can be applied to other semiconductor devices where the electronic component is connected to the substrate via the interconnect.

FIG. 2A shows a cross-sectional view of an example bonder tool for bonding an example semiconductor device. In the example shown in FIG. 2A, laser-assisted-bonding (LAB) tool 15 can comprise laser source 151, stage block (or base chuck) 152, and window 153.

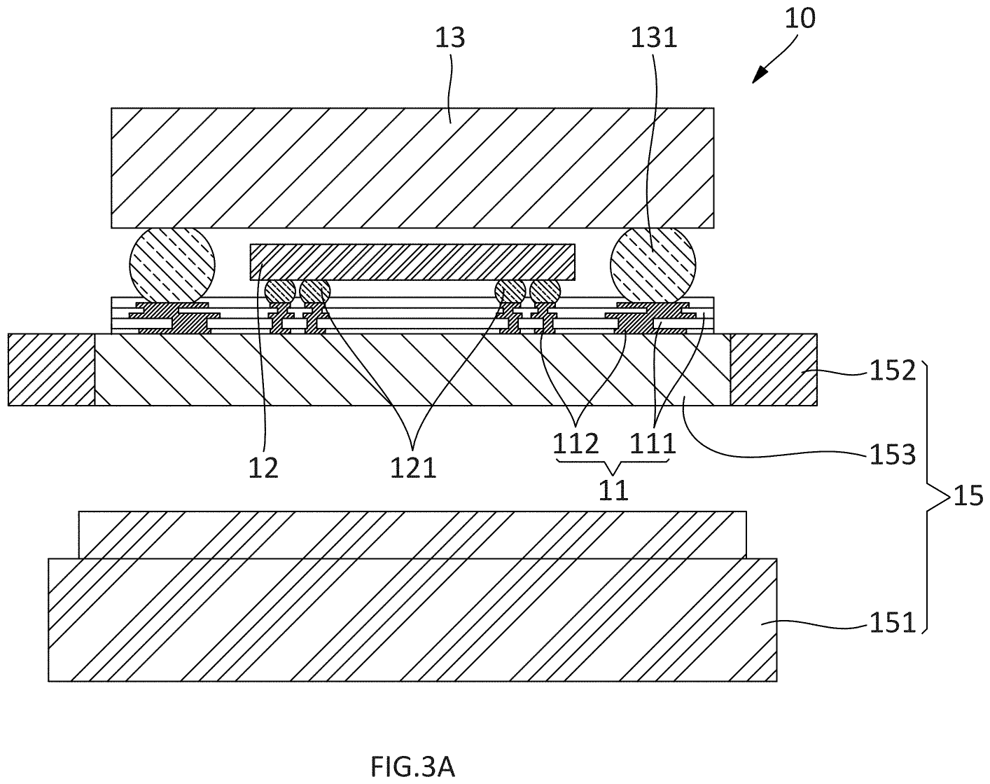

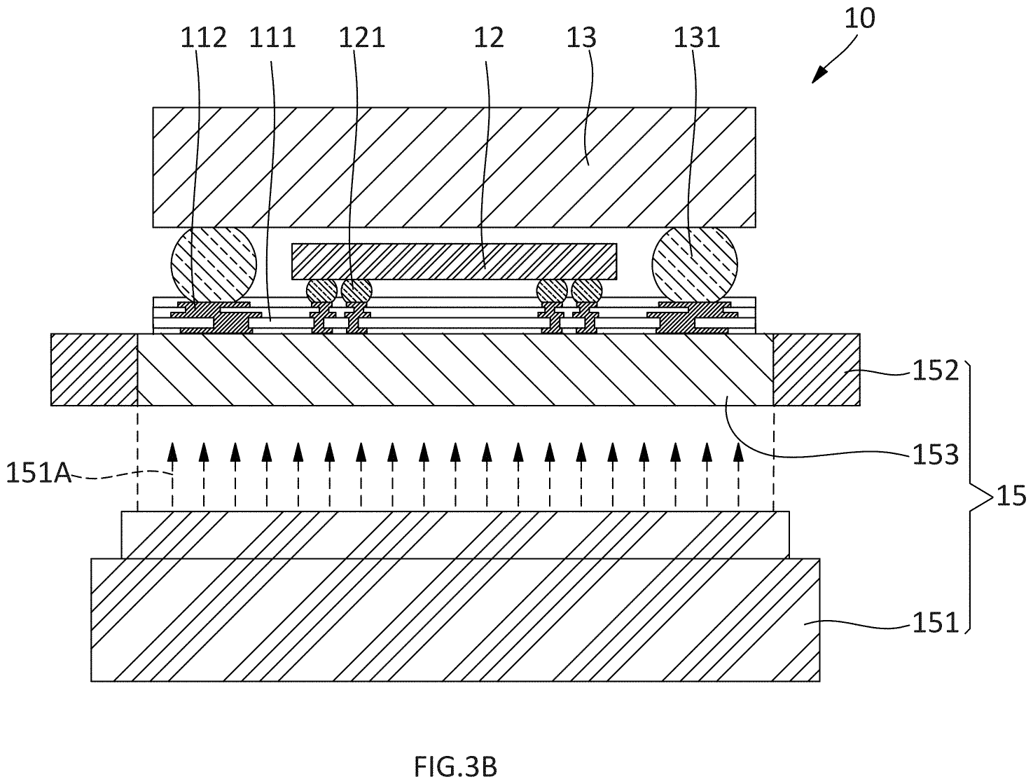

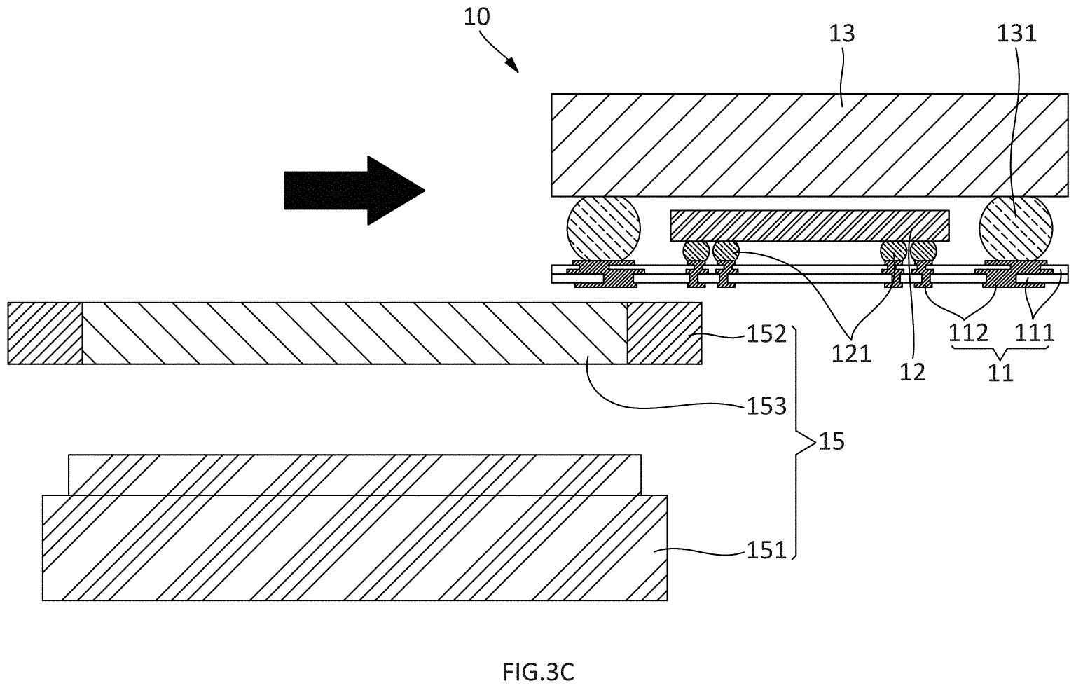

Laser source 151 can irradiate laser beams 151A through window 153 as shown in FIG. 3B. Stage block 152 can comprise or accommodate window 153. In some examples, window 153 can comprise an opening through stage block 152. In some examples, the opening can be filled or covered with a transparent material such as glass or quartz, or a grating or similar structure that lets light through. In some examples, stage block 152 can comprise a ceramic material, or a portion of stage block 152 such as window 153 can comprise a ceramic material. In such examples, a ceramic stage tool can be heated by an external heat source such as laser source 151 using laser beams 151A to accelerate the bonding process through the heating of the ceramic material. In some examples where window 153 comprises a ceramic, the laser beams 151A do not pass through window 153 but operate to heat the ceramic window 153 which in turn heats the semiconductor device 30. In contrast, where the window 152 is transparent, semiconductor device 30 can be heated by passing the laser beams 151A through the window 152 to heat semiconductor device 30 during the bonding process. In some examples the opening through stage block 152 can be optional, where stage block 152 can be itself made of the transparent material, or where window 153 defines the upper surface of stage block 152. Window 153 can be used to support one or more substrates, such as substrates 11 introduced in FIG. 1A to FIG. 1C. Laser beams 151A generated from laser source 151 can be transmitted through window 153 to cause bonding of interconnects 121, 131, or 141 of electronic components 12, 13, or 14 with terminals of conductive structure 112 of substrate 11 as shown in FIG. 1A to FIG. 1C. In some examples, window 153 can comprise a material exhibiting any amount of light transmissivity to allow light at the desired wavelength to pass through, for example at or near the wavelength of laser beams 151A.

FIG. 2B shows a cross-sectional view of an example hybrid bonder tool for bonding an example semiconductor device. In the example shown in FIG. 2B, hybrid bonder tool 40 can comprise laser-assisted bonder (LAB) tool 15 and thermal/compression bonding (TCB) tool 35.

LAB tool 15 can comprise laser source 151, stage block 152, and window 153. LAB tool 15 can be similar to LAB tool 15 shown in FIG. 2A. Thermal/compression bonder tool 35 can comprise thermal/vibration/compression plate 351 and heater source 352.

FIGS. 3A to 3C show cross-sectional views of an example method for bonding an example semiconductor device. In FIGS. 3A to 3C, the example semiconductor device can be semiconductor device 10 shown in FIG. 1A.

FIG. 3A shows semiconductor device 10 and laser-assisted bonder (LAB) tool 15 before laser beam irradiation in a bonding process. Electronic components 12 or 13 are shown placed on substrate 11 but not yet fully bonded to substrate 11 through interconnect 121 or 131, respectively. In some examples, electronic components 12 or 13 can be temporarily bonded or pre-bonded to substrate 11 through interconnect 121 or 131, respectively. In some examples, an electronic component 12 or 13 is provided over substrate 11 such that an interconnect 121 or 131 of the electronic component contacts conductive structure 112 of substrate 11. Substrate 11 can be provided over LAB tool 15 that comprises stage block 152 comprising window 153.

Substrate 11 comprises conductive structure 112 having one or more conductive layers or patterns, and dielectric structure 111 having one or more dielectric layers interlaced with conductive structure 112. In some examples, substrate 11 can have a thickness in the range from about 10 micrometers (μm) to about 2,000 μm. Electronic components 12 or 13 can comprise or be referred to as semiconductor dies, semiconductor chips, or semiconductor packages. In some examples, such semiconductor packages can comprise one or more semiconductor dies or chips coupled to a substrate and encapsulated, with interconnects 121 or 131 exposed. In some examples, interconnect 121 or 131 of electronic components 12 or 13 can be placed in a flip chip type configuration on terminals, such as pads or UBMs (Under-Bump Metallizations), of conductive structure 112 of substrate 11.

In some examples, electronic components 12 or 13 can comprise an application specific integrated circuit, a logic die, a micro control unit, a memory, a digital signal processor, a network processor, a power management unit, an audio processor, a radio-frequency (RF) circuit, or a wireless baseband system on chip processor. In some examples, electronic components 12 or 13 can comprise an active component or a passive component. Electronic components 12 or 13 can have a thickness in the range from about 10 μm to about 1,000 μm.

Interconnects 121 or 131 can electrically connect electronic components 12 or 13 to conductive structure 112 of substrate 11, respectively. Interconnects 121 or 131 can comprise conductive balls or bumps, such as solder balls or bumps, conductive pillars or posts such as copper pillars or posts with solder tips, or metal-core solder balls or bumps having a core comprising, for example, copper or aluminum surrounded by a solder shell. Interconnects 121 or 131 can have diameter in the range from about 10 μm to about 1,000 μm. In some examples, interconnects 121 or 131 can first be formed on or attached to electronic components 12 or 13, and then interconnects 121 or 131 can be placed on substrate 11.

In the example shown in FIG. 3A, LAB tool 15 can be positioned below semiconductor device 10. LAB tool 15 can irradiate laser beams from laser source 151 to melt or reflow interconnects 121 or 131 and bond electronic components 12 or 13 to substrate 11. Melting can comprise heating interconnects to at least partially melt them so they can bond with an adjacent conductive structure, such as conductive structure 112 of substrate 11. In some examples, melting can be referred as reflowing. In some examples, electronic components 12 or 13 can be permanently bonded to substrate 11.

In the example shown in FIG. 3A, stage block 152 can be spaced apart from laser source 151 and can be positioned above laser source 151. Stage block 152 can be spaced a working distance apart from laser source 151. In some examples, the working distance can range from about 100 millimeters (mm) to about 1000 mm. The working distance can be preset and can be changed before or during laser irradiation. Stage block 152 can be installed to cover or support peripheries of window 153. Stage block 152 can be provided to cover at least some portions or the whole of the peripheries of window 153. In some examples, a periphery of window 153 or of substrate 11 can rest over stage block 152.

In the example shown in FIG. 3A, window 153 can be coupled to stage block 152. Window 153 can be spaced a working distance apart from laser source 151. The working distance between window 153 and laser source 151 can be similar to the working distance between stage block 152 and laser source 151. Window 153 can support semiconductor device 10.

Window 153 can be made of a material capable of permitting passage of laser beams. In some examples, window 153 can be made of quartz or glass. In some examples, window 153 can be a void or a passageway defined by the inner sidewalls of stage block 152. In some examples, window 153 can comprise a material exhibiting any amount of light transmissivity to allow light at the desired wavelength to pass through, for example at or near the wavelength of laser beams 151A. In some examples, the transmittance of window 153 for laser beams can be about 90% or greater to facilitate the LAB process. In some examples, the transmittance of window 153 can be less than 90%. In some examples, window 153 can comprise a grating or other structure to allow at least some amount of light to pass through. In some examples, window 153 can have a thickness in the range from about 1 mm to about 300 mm. In some examples, stage block 152 can support a workpiece worked on by LAB tool 15. The workpiece an comprise, for example, substrate 11, or electronic component 12 or 13 over substrate 11 including interconnects 121 or 131.

FIG. 3B shows semiconductor device 10 and LAB tool 15 while laser beams are being irradiated during the bonding process. As shown in FIG. 3B, laser beams 151A are irradiated from laser source 151, and heat can be applied or transferred to interconnects 121 or 131 through window 153 and substrate 11. In some examples, when laser beams 151A are irradiated from laser source 151, substrate 11 can be heated and such heat can be transferred to interconnects 121 or 131. In some examples, when laser beams 151A are irradiated from laser source 151, heat can be applied to interconnects 121 or 131. In some examples, such heat can be applied to interconnects 121 or 131 while maintaining the temperature of substrate 11 lower than the temperature of heated interconnects 121 or 131. For instance, interconnects 121 or 131 can be positioned at a focal length or a focal distance, within a depth of field (DOF) range of laser beams 151A. In some examples, such focusing of laser beams 151A on interconnects 121 or 131 can permit greater heating of interconnects 121 or 131 than of substrate 11 or electronic components 12 or 13. With such heating by laser beams 151A, interconnects 121 or 131 can be melted for bonding between substrate 11 and electronic components 12 or 13, which can be permanent bonding in some examples. Laser source 151 can be sized to be larger than the overall size of substrate 11 or can be configured to irradiate with laser beams 151 the entire bottom side of substrate 11 exposed through window 153. Interconnect 121 or 131 of electronic component 12 or 13 can be heated with a laser beam 151A through the window 153 of stage block 152 until the interconnect 121 or 131 is bonded with conductive structure 112 of substrate 11. In some examples, interconnect 121 or 131 can be within the depth of field (DOF) when interconnect 121 or 131 is heated.

In the example shown in FIG. 3B, laser beams 151A are indicated by arrows. Substrate 11 and interconnects 121 or 131 can be positioned within an area where an appropriate temperature for melting interconnects 121 or 131 can be maintained when laser beams 151A are irradiated. The irradiation range of laser beams 151A can vary depending on the thickness and transmittance of window 153 or the working distance. Laser beams 151A can be generated from a pulsed laser or a continuous laser. In some examples, electronic component 12 or 13 can be over a first side of substrate 11, and laser beam 151A can be applied to interconnect 121 or 131 from a second side of substrate 11 opposite to the first side. In some examples, stage block 152 can support window 153 and substrate 11 over laser beam 151A.

In some examples, laser beams 151A can have energy in the range from about 0.1 kilowatts (kW) to about 16 kW to properly heat or melt interconnects 121 or 131 and to avoid undue heating or damage of dielectric structure 111 or conductive structure 112 of substrate 11. In some examples, laser source 151 can output one or more of laser beams 151A with energy up to approximately 0.1 kW to about 100 kW, whether aimed at specific areas of stage block 152 or substrate 11, or evenly distributed across. In some examples, laser beams 151A can have wavelengths from about 600 μm to about 2,000 μm to properly heat or melt interconnects 121 or 131 and to avoid undue heating or damage of dielectric structure 111 or conductive structure 112 of substrate 11. In some examples, laser beams 151A can be irradiated for a time in the range from about 100 milliseconds (ms) to about 30,000 ms to properly heat or melt interconnects 121 or 131 and to avoid undue heating or damage of dielectric structure 111 or conductive structure 112 of substrate 11. For instance, laser beams 151A can be irradiated for about 2000 ms or less, or about 1000 ms or less, to properly heat and bond interconnects 121 or 131 with substrate 11. In some examples, the temperature of substrate 11 can be maintained at a temperature lower than a temperature of interconnect 121 or 131 when heat is applied to interconnect 121 of 131 from laser beam 151A. In some examples, the temperature of electronic component 12 or 13 can be maintained lower than a temperature of interconnect 121 or 131 when heat is applied to interconnect 121 or 131 from laser beam 151A. In further examples, a temperature of a mold compound or a molded package adjacent to electronic component 12 or 13 can be maintained lower than a temperature of interconnect 121 or 131 when heat is applied to interconnect 121 or 131 from laser beam 151A.

In some examples, when laser beams 151A are irradiated, substrate 11 can be at a temperature in the range from about 30 degrees Celsius (° C.) to about 300° C. to properly heat or melt interconnects 121 or 131 and to avoid undue heating or damage of dielectric structure 111 or conductive structure 112 of substrate 11. For instance, heat caused by laser beams 151A on substrate 11 or interconnects 121,131 can be in the range from about 150° C. to about 350° C., such as from about 230° C. to about 280° C. In some examples, when laser beams are irradiated, window 153 can be at a temperature in the range from about 30° C. to about 300° C. In some examples, the temperature of window 153 can be maintained at a range from about 25° C. to about 150° C., such as from about 70° C. to about 130° C., lower than a melting temperature of interconnects 121 or 131.

FIG. 3C shows LAB tool 15 after the bonding process is completed. In the example shown in FIG. 3C, when bonding between substrate 11 and electronic components 12 or 13 is completed, irradiation of laser beams 151A can be stopped, and semiconductor device 10 can be transferred to a next stage. When irradiation of laser beams 151A is stopped, supply of the heat from laser beams can be immediately interrupted. As such, since the supply of heat by the laser beams is stopped, interconnects 121 or 131 can be solidified again. Solidified interconnects 121 or 131 can allow an electrical or mechanical interconnection between electronic components 12 or 13 and the substrate 11. Bonding of a next semiconductor device can be performed immediately using laser beams 151A, without a separate cooling process.

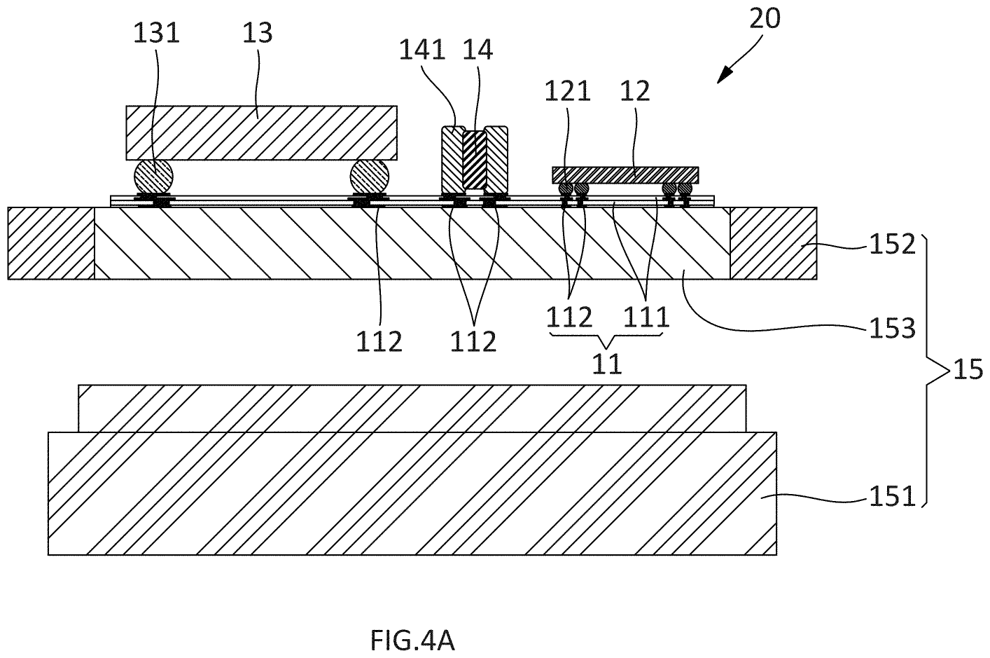

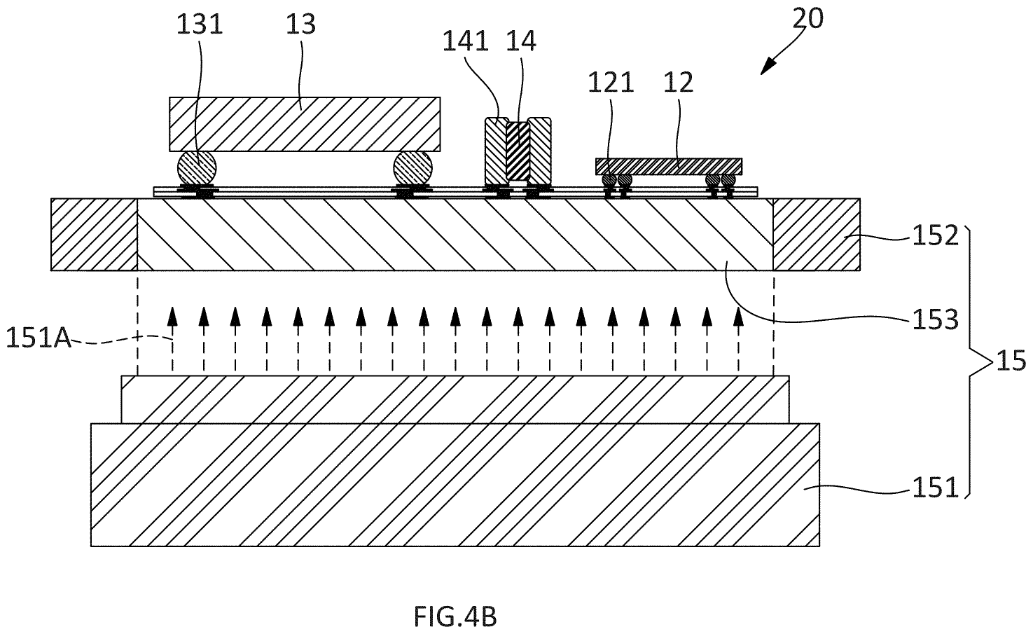

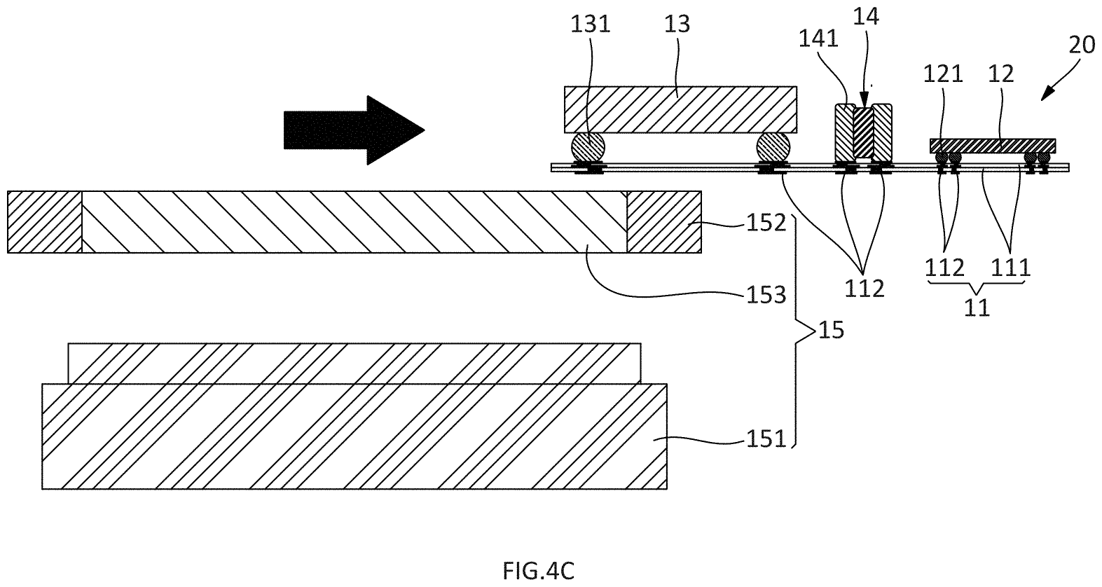

FIGS. 4A to 4C show cross-sectional views of an example method for bonding an example semiconductor device. The example semiconductor device 20 shown in FIGS. 4A to 4C can be similar to semiconductor device 20 shown in FIG. 1B.

FIG. 4A shows semiconductor device 20 and laser-assisted bonder (LAB) tool 15 before laser beams 151A are being irradiated during a bonding process. FIG. 4B shows semiconductor device 20 and LAB tool 15 while laser beams 151A are irradiated during the bonding process. FIG. 4C shows LAB tool 15 after the bonding process is completed. In the examples shown in FIGS. 4A to 4C, substrate 11, electronic components 12 or 13 and interconnects 121 or 131 of semiconductor device 20 can be similar to those of semiconductor device 10 shown in FIGS. 3A to 3C.

Electronic component 14 can comprise a passive component or passive devices. Electronic component 14 can be temporarily connected to conductive structures 112 of substrate 11 through interconnects 141. In some examples, electronic component 14 can comprise at least one of a resistor, a capacitor, an inductor, or a connector. Electronic component 14 can have a thickness in the range from about 0.1 mm to about 3 mm.

In the example shown in FIG. 4A, LAB tool 15 can be positioned below semiconductor device 20. LAB tool 15 can irradiate laser beams 151A from laser source 151 to melt interconnects 121 or 131,141 and to bond electronic components 12 or 13,14 to substrate 11.

In the example shown in FIG. 4A-4C, laser source 151, stage block 152 and window 153 of LAB tool 15 can be similar to those of LAB tool 15 describe with respect to FIGS. 3A-3C. The example method shown in FIGS. 4A-4C can be similar to that described with respect to FIGS. 3A-3C.

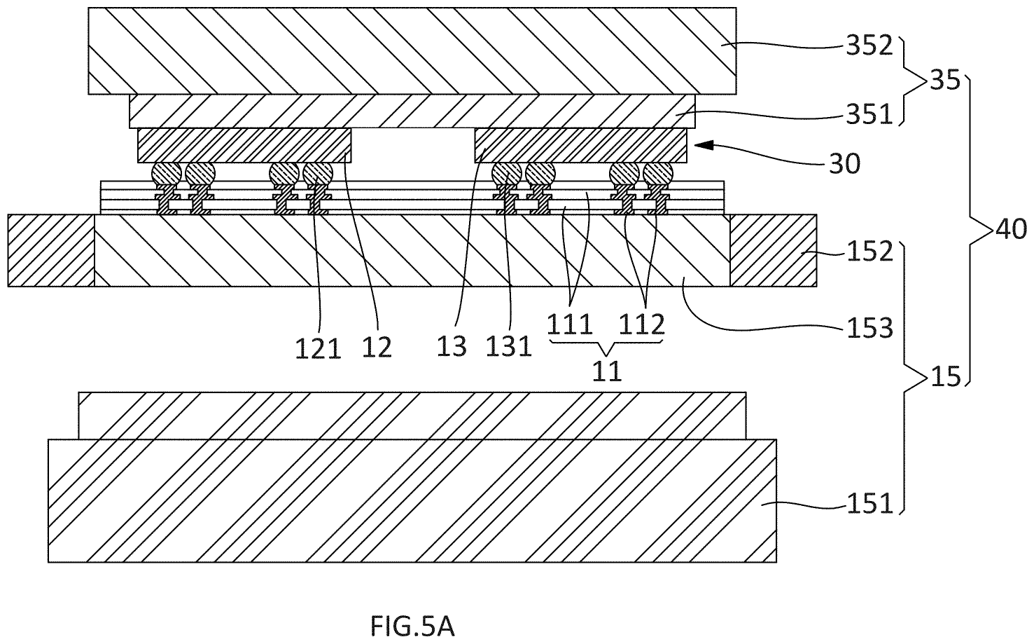

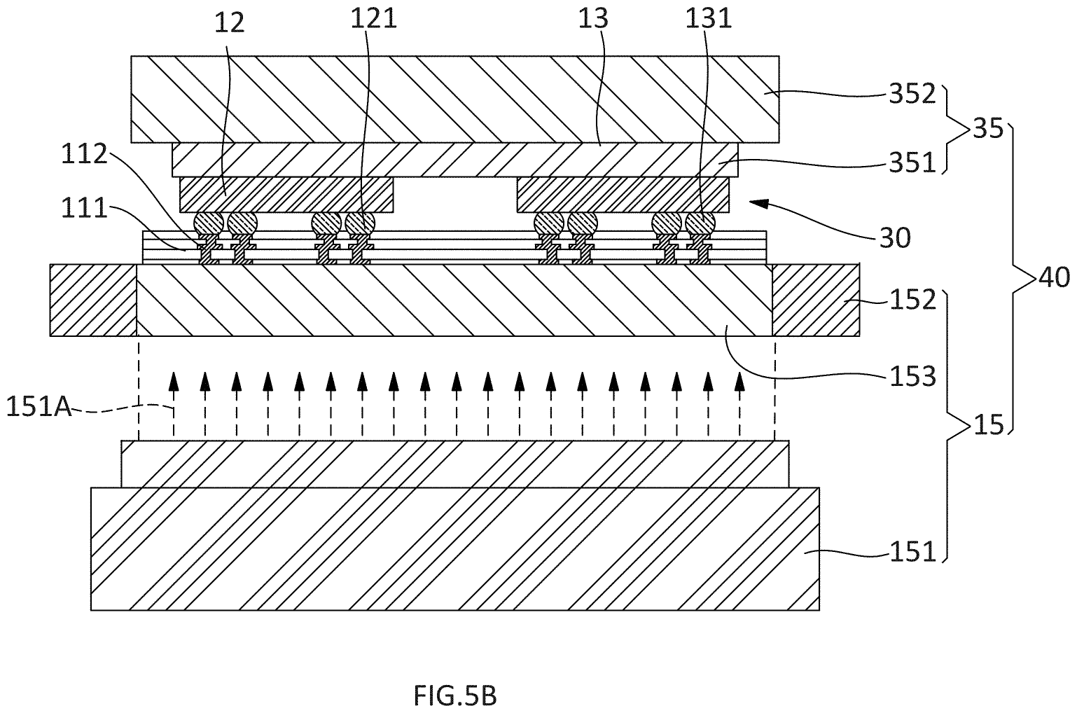

FIGS. 5A to 5C show cross-sectional views of an example method for bonding an example semiconductor device. The example semiconductor device shown in FIGS. 5A to 5C can be similar with the semiconductor device 30 shown in FIG. 1C.

FIG. 5A shows semiconductor device 30 and hybrid bonder tool 40 before laser beam irradiation in a bonding process. In the examples shown in FIGS. 5A to 5C, substrate 11, electronic component 12,13 and interconnects 121,131 of semiconductor device 30 can be similar to substrate 11, electronic components 12 or 13 and interconnects 121 or 131 of semiconductor device 10 shown in FIGS. 3A to 3C. In some examples, electronic component 12 or 13 can be provided over one side of substrate 11 such that an interconnect 121 or 131 of electronic component 12 or 13 contacts conductive structure 112 of substrate 11.

In some examples, electronic component 12 or 13 could be prone to warpage during laser bonding using LAB tool 15 and the process of FIGS. 3A-3C. For instance, heat from laser beams 151A in FIG. 3B can be transferred to electronic component 12 or 13 during the bonding process thereby resulting in warpage occurring to electronic component 12 or 13. Such warpage can happen, for example, if the area of electronic component 12 or 13 is sufficiently large, or the thickness or electronic component 12 or 13 is sufficiently thin, relative to the amount of heat transferred during LAB bonding. To avoid or prevent warpage, the bonding process of semiconductor device 30 can be performed by hybrid bonder tool 40. Furthermore, although FIGS. 5A-5C show a semiconductor device 30 comprising two separate and smaller electronic components 12 and 13, in some examples semiconductor device 30 can comprise a single electronic component 12 that can be longer or larger or thinner than electronic components 12 or 13 as shown in FIGS. 5A-5C. In such examples, a longer, larger, or thinner die such as electronic component 12 may be susceptible to warpage and non-wet interconnects 121, for example near the edges of electronic component 12. In some examples, semiconductor device 30 can comprise a single electronic component 12, or semiconductor device 30 can comprise multiple electronic components 12 and 13 as shown in FIG. 5A. In some examples where semiconductor device 30 comprises a single electronic component, electronic component 12 can comprise a larger area or thinner die thickness. For instance, electronic component 12 can comprise an area from about 1 mm by 1 mm up to about 300 mm by 300 mm, or a thickness of about 30 μm to about 1 mm or 10 mm. In some examples, semiconductor device 30 can comprise a package in addition to a die, for example an electronic component comprising a die or electronic component 12, interposer, substrate, or interconnects in a package structure. The susceptibility to warpage and non-wet interconnects 121 by such larger area semiconductor devices 30 can be avoided or mitigated by using vacuum. For example, window 153 can comprise one or more vacuum holes therethrough to allow the application of vacuum to semiconductor device 30. Lab tool 15 can include a vacuum mechanism to apply vacuum through the vacuum holes of window 153 to force semiconductor device 30 including substrate 11 against window 153 during heating to prevent warpage of substrate 11. In some examples, TCB tool 35 can also include a vacuum mechanism, or can employ the same vacuum mechanism as LAB tool 15, to apply a vacuum to semiconductor device 30 from the opposite side as LAB tool 15. In such examples, plate 351 can comprise one or more vacuum holes for the application of a vacuum to maintain or force electronic component 12,13 against plate 351 to prevent warpage of electronic component 12,13 and to prevent non-wetting of interconnects 121,131 during heating.

In the example shown in FIG. 5A, hybrid bonder tool 40 can comprise LAB tool 15 to irradiate laser beams 151A from laser source 151 positioned below semiconductor device 30 for bonding electronic components 12 or 13 to substrate 11. Hybrid bonder tool 40 can also comprise TCB tool 35 to also bond electronic components 12 or 13 to substrate 11 while preventing warpage of electronic components 12 or 13. TCB tool 35 can comprise plate 351 and heater source 352, and can compress or provide backing for electronic component 12,13 from above while heat is applied to limit warpage of electronic component 12,13 during the bonding process. Plate 351 can be configured to press a top side of electronic component 12 or 13 opposite interconnect 121 or 131 when laser 151A of LAB tool 15 applies heat to interconnect 121 or 131. Plate 351 can be configured to transfer heat, vibration, or compression to interconnect 121 or 131 when thermal/compression plate 315 presses top side of electronic component 12 or 13.

TCB tool 35 can be positioned above LAB tool 15. In some examples, plate 351 can be initially positioned spaced apart from electronic component 12,13 and can then be lowered after semiconductor device 30 is placed on window 153. Plate 351 can be brought into contact with a top of electronic component 12,13 to maintain pressure on electronic component 12,13 against substrate 11. Plate 351 can apply pressure on electronic component 12,13 with a pressure as low as about 0.1 Newton (N), such as in the range from about 1 N to about 500 N. In some examples, plate 351 can have a thickness in the range from about 1 mm to about 5 mm.

In some examples, plate 351 can vacuum-latch electronic component 12,13 while simultaneously compressing electronic component 12,13. In some examples, vacuum latching can be achieved by coupling plate 351 to a vacuum generator that creates vacuum suction through openings at the bottom side of plate 351 and exposing the top side of electronic component 12 or 13 to such vacuum openings of plate 351. When the heat is transferred to electronic component 12 or 13, plate 351 can remain latched to electronic component 12 or 13 while compressing electronic component 12 or 13 from above to prevent electronic component 12 or 13 from being warped.

Plate 351 can be coupled with heater source 352 for heating thermal/compression plate 351, and such heat can be transferred to electronic component 12 or 13 when plate 351 is brought into contact with electronic component 12 or 13. In some examples, heater source 352 can be maintained at a preset temperature in the range from about 10° C. to about 450° C.

In some examples, TCB tool 35 can be configured to vibrate plate 351 or induce vibration of electronic component 12 or 13 against substrate 11, where such vibration can induce heat due to friction on interconnects 121 or 131. In some examples such vibration-induced heat on interconnects 121 or 131 can cause or aid in the bonding of interconnects 121 or 131 with substrate 11.

The heat transferred from plate 351 to electronic component 12 or 13 can prevent warpage that could otherwise occur due to a mismatch between the temperature of the top and bottom sides of electronic component 12 or 13. For instance, when only LAB tool 15 is used, laser beams 151A can cause the bottom side of electronic component 12 or 13 to be heated more, and to thus expand more, than the top side of electronic component 12 or 13 wherein such difference can induce warpage. By applying compensatory heat with plate 351 to the top side of electronic component 12 or 13, such warpage tendency can be controlled. In some examples, a temperature of substrate 11 can be maintained lower than a temperature of interconnect 121 or 131 when heat is applied to interconnect 121 or 131 from LAB tool 15. In some examples, a temperature of electronic component 12 or 13 with TCB tool 35 can be maintained lower than a temperature of interconnect 121 or 131 when heat is applied to interconnect 121 or 131 from LAB tool 15.

FIG. 5B shows semiconductor device 30 and LAB tool 15 while laser beams 151A are being irradiated during the bonding process. In the example shown in FIG. 5B, an example method for bonding semiconductor device 30 to substrate 11 by irradiating laser beams 151A from laser source 151 to melt interconnects 121,131 of semiconductor device 30 can be similar to the example method shown in FIGS. 3B and 4B. In the example shown in FIG. 5B, during the bonding process, thermal/compression bonder tool 35 can compress or heat electronic devices 12 or 13 from above. In some examples, heat can be applied to interconnect 121 or 131 with laser beam 151A from LAB tool 15 through a substrate side opposite to the side on which electronic component 12 or 13 is positioned. Heat, vibration, or compression can be applied to interconnect 121 or 131 with TCB tool 35 through electronic component 12 or 13. In some examples, laser beam 151A can have a depth of field (DOF), and interconnect 121 or 131 can be in the DOF when heated. In some examples, LAB tool 15 and TCB tool 35 can be applied concurrently. In some examples, window 153 can face or contact a side of substrate 11 opposite to the side of substrate 11 on which electronic component 12 or 13 is located when heat is applied by LAB tool 15.

FIG. 5C shows LAB tool 15 after the bonding process is completed. In the example shown in FIG. 5C, once bonding of substrate 11 and electronic component 12 or 13 is completed, irradiation of laser beams 151A can be interrupted, and thermal/compression bonder tool 35 can be separated from semiconductor device 30 and then elevated. After thermal/compression bonder tool 35 is separated from semiconductor device 30, semiconductor device 30 can be transferred to a next stage.

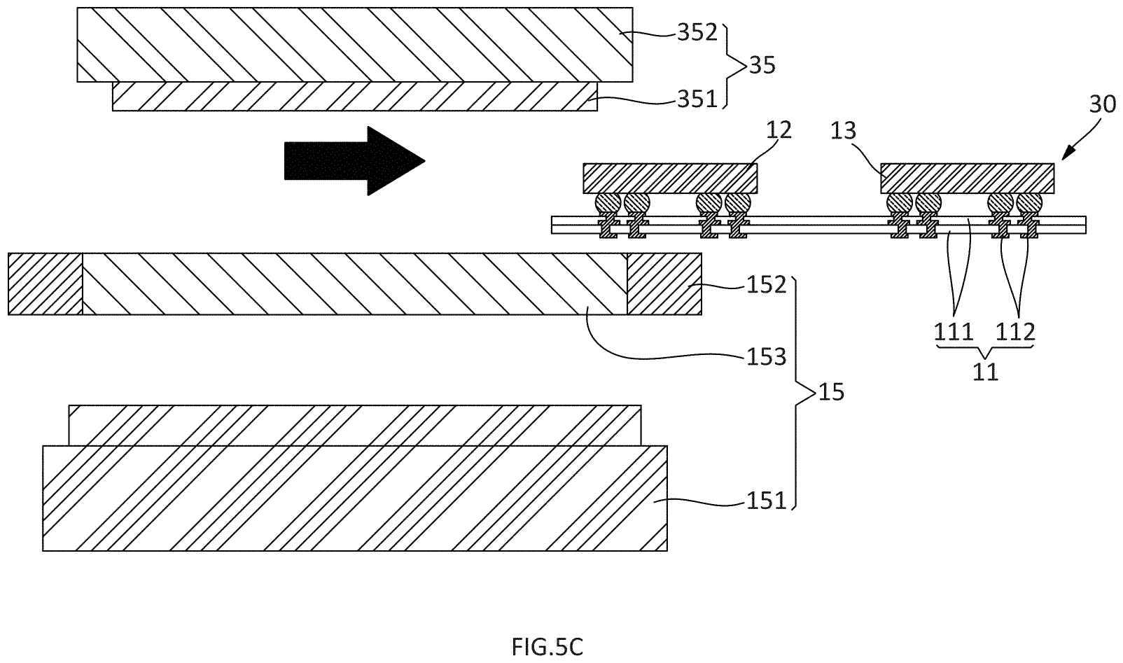

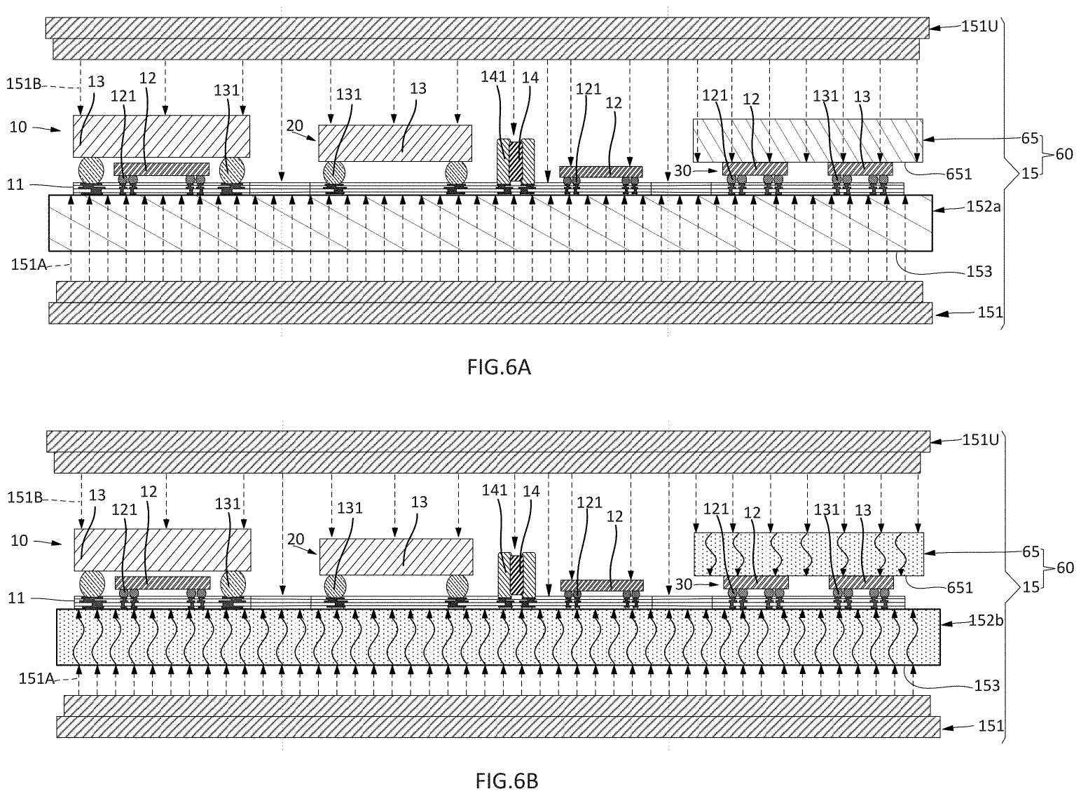

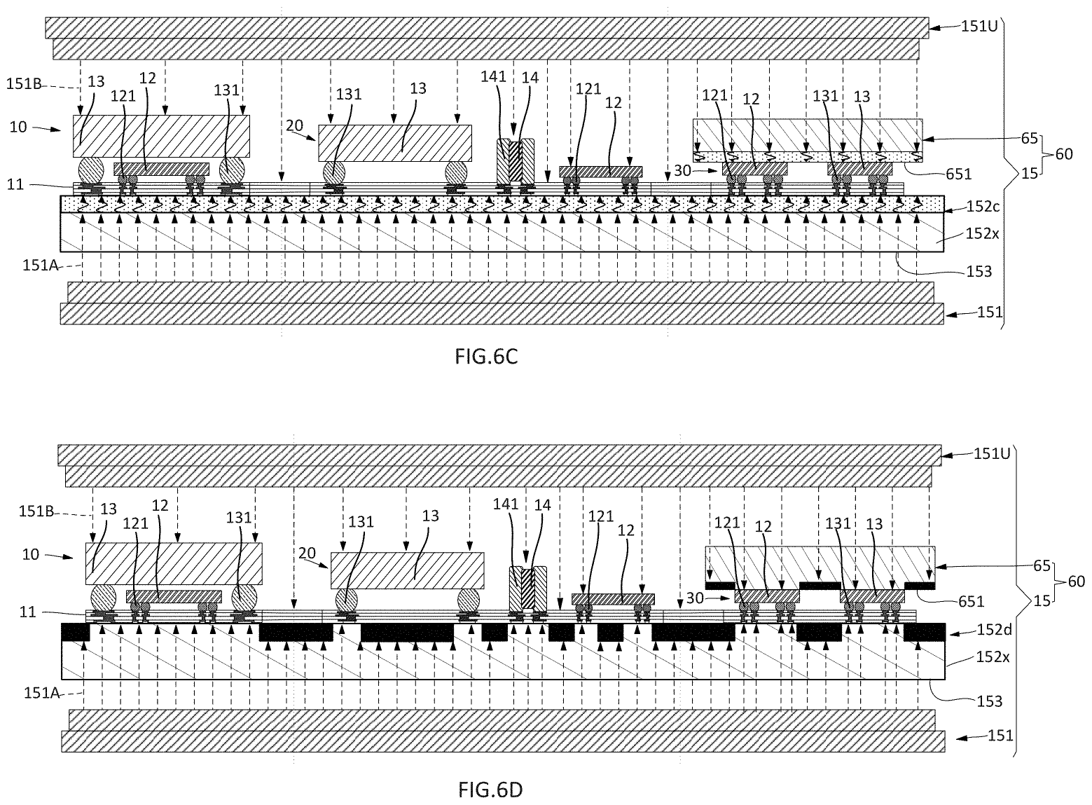

FIGS. 6A to 6D show detailed cross-sectional views of example bonding stages using LAB tool 15, further detailing the bonding stages described with respect to FIGS. 3B, 4B, 5B for semiconductor devices 10, 20, 30.

FIG. 6A shows semiconductor devices 10, 20, 30 and LAB tool 15 while laser beams are being irradiated during the bonding process. FIG. 6A is similar to, and shares corresponding description as FIGS. 3B, 4B, 5B. Lab tool 15 shares corresponding features and elements as described with respect to FIG. 2. TCB tool 35 can optionally be included along with LAB tool 15 for hybrid bonding of semiconductor device 30 as previously described with respect to FIG. 5.

As previously described with respect to stage block 152, in some examples stage block 152a can comprise a transparent material, such as glass or quartz, that permits laser beams 151A to pass through stage block 152a. As also previously described, in some examples the transmittance through stage block 152a can be about 90% or greater for laser beams 151a to facilitate the LAB bonding process.

As shown, laser beams 151A are irradiated from laser source 151 towards stage block 152a, and such laser beams 151A can pass through stage block 152a, such as through window 153 portion of stage block 152a, to reach substrate 11 of semiconductor device 10, 20, 30. Laser beams 151A can transfer or induce heat to interconnects, 121, 131, 141. In some examples, laser beams 151A can reach substrate 11 though stage block 152a, can then pass through substrate 11, and can then reach interconnects, 121, 131, 141 and heat them through heat irradiation. In some examples, interconnects 121, 131, 141 can be positioned at a focal length or a focal distance, within a depth of field (DOF) range of laser beams 151A, and such focusing of laser beams 151A on interconnects 121, 131, 141 can permit greater heating of interconnects 121, 131, 141 than of substrate 11 or electronic components 12, 13, 14. In some examples, laser beams 151A can reach substrate 11 through stage block 152a, can then induce heat on one or more areas of substrate 11, and such heated substrate areas can heat interconnects 121, 131, 141 through heat conduction.

Interconnects 121, 131, 141 of can be heated until bonded with conductive structure 112 of substrate 11. Heat and time parameters can be properly controlled to minimize bonding time for fast throughput while avoiding exposure to higher temperatures to minimize undue thermal expansion or warpage of substrate 11. In some examples, laser beams 151A can be irradiated for about 2000 ms or less, or about 1000 ms or less, to cause proper heating and bonding of interconnects 121,131,141 with substrate 11. In some examples, heat caused by laser beams 151A on interconnects 121, 131, 141 or on substrate 11 can be controlled to remain under about 300° C. or 350° C., such as in the range from about 150° C. to about 350° C., or from about 230° C. to about 280° C.

FIG. 6B shows semiconductor devices 10, 20, 30 and LAB tool 15 while laser beams are being irradiated during the bonding process. FIG. 6B is similar to, and shares corresponding description as FIGS. 3B, 4B, 5B. Lab tool 15 shares corresponding features and elements as described with respect to FIG. 2. TCB tool 35 can optionally be included along with LAB tool 15 for hybrid bonding of semiconductor device 30 as previously described with respect to FIG. 5.

As previously described, with respect to stage block 152, in some examples stage block 152b can comprise an opaque material, such as ceramic, that obstructs or blocks laser beams 151A from passing through stage block 152b. In some examples, the opaque material of stage block 152b can comprise a metal material. As also previously described, in some examples the transmittance through stage block 152 can be less than 90%, such as 0%, for laser beams 151A.

As shown, laser beams 151A are irradiated from laser source 151 towards stage block 152b, such as towards window 153 portion of stage block 152b. Such laser beams 151A are substantially blocked by stage block 152b, but they can heat stage block 152b, such as by heat irradiation. In turn, such heat in heated stage block 152b, represented by the wavy upward arrows, can be transferred to heat interconnects, 121, 131, 141. In some examples, the heat from stage block 152b reaches and extends through substrate 11 to heat interconnects 121, 131, 141 by heat conduction.

Interconnects 121, 131, 141 of can be heated until bonded with conductive structure 112 of substrate 11. Heat and time parameters can be properly controlled to reduce bonding time while avoiding exposure to higher temperatures to minimize undue thermal expansion or warpage of substrate 11. In some examples, laser beams 151A can be irradiated for about 10000 ms to about 30000 ms, or even longer term to about 10 minutes, to cause proper heating and bonding of interconnects 121,131,141 with substrate 11. In some examples, heat caused by laser beams 151A on interconnects 121, 131, 141 or on substrate 11 can be controlled to remain under about 300° C. or 350° C., such as in the range from about 150° C. to about 350° C., or from about 230° C. to about 280° C.

FIG. 6C shows semiconductor devices 10, 20, 30 and LAB tool 15 while laser beams are being irradiated during the bonding process. FIG. 6C is similar to, and shares corresponding description as FIGS. 3B, 4B, 5B. Lab tool 15 shares corresponding features and elements as described with respect to FIG. 2. TCB tool 35 can optionally be included along with LAB tool 15 for hybrid bonding of semiconductor device 30 as previously described with respect to FIG. 5.

In some examples stage block 152c can comprise a combination of transparent and opaque materials. For example, stage block 152c can comprise a stack of transparent material portion 152x and opaque material portion 152y. Features or materials, or characteristics of transparent portion 152x can be similar to those described with respect to stage block 152a. Features or materials, or characteristics of opaque portion 152y can be similar to those described with respect to stage block 152b.

As shown, laser beams 151A are irradiated from laser source 151 towards stage block 152c, and such laser beams 151A can pass through transparent material portion 152x of stage block 152c to reach opaque material portion 152y. Laser beams 151A are substantially blocked from passing through by opaque material portion 152y, but they can heat opaque material portion 152y or transparent material portion 152x by, for example, heat irradiation, such that the top of stage block 152c is heated. In turn such heat, represented by the wavy upward arrows, can be transferred to heat interconnects 121, 131, 141. In some examples, the heat from stage block 152c is transferred by heat conduction to extend through substrate 11 and to heat interconnects 121, 131, 141. Interconnects 121, 131, 141 of can be heated until bonded with conductive structure 112 of substrate 11. In some examples, because laser beams 151A are obstructed by opaque material portion 152y from reaching substrate 11, heating of substrate 11 or interconnects 121, 131, 141 through heat conduction can be controlled to remain lower than if laser beams 151A reached and heated substrate 11 through heat irradiation. Such heat control can be used to prevent or restrict undue thermal expansion or warpage of substrate 11.

There can be examples where a thickness of transparent portion 152x can be greater than the thickness of opaque portion 152y. For instance, transparent portion 152x can range in thickness from about 1 mm to about 300 mm, and opaque portion 152y can range in thickness from about 100 μm to about 100 mm. In some examples, opaque portion 152y can comprise one or more plating layers that covers transparent portion 152x.

Interconnects 121, 131, 141 of can be heated until bonded with conductive structure 112 of substrate 11. Heat and time parameters can be properly controlled to reduce bonding time while avoiding exposure to higher temperatures to minimize undue thermal expansion or warpage of substrate 11. In some examples, laser beams 151A can be irradiated for about 5000 ms to about 20000 ms, to cause proper heating and bonding of interconnects 121,131,141 with substrate 11. In some examples, heat caused by laser beams 151A on interconnects 121, 131, 141 or on substrate 11 can be controlled to remain under about 300° C. or 350° C., such as in the range from about 150° C. to about 350° C., or from about 230° C. to about 280° C.

FIG. 6D shows semiconductor devices 10, 20, 30 and LAB tool 15 while laser beams are being irradiated during the bonding process. FIG. 6D is similar to, and shares corresponding description as FIGS. 3B, 4B, 5B. Lab tool 15 shares corresponding features and elements as described with respect to FIG. 2. TCB tool 35 can optionally be included along with LAB tool 15 for hybrid bonding of semiconductor device 30 as previously described with respect to FIG. 5.

Stage block 152d can be an implementation of stage block 152 described with respect to FIGS. 1-5. As previously described with respect to stage block 152, in some examples stage block 152d can comprise a grating that permits some amount of laser to pass through. In some examples stage block 152d can comprise a combination of transparent and opaque materials. For example, stage block 152d can comprise a stack of transparent material portion 152x and opaque material portion 152z. Features or materials, or characteristics of transparent portion 152x can be similar to those described with respect to stage block 152a. Features or materials, or characteristics of opaque portion 152z can be similar to those described with respect to stage block 152b or opaque portion 152y.

Opaque portion 152z comprises a grating or pattern of openings through the opaque material that selectively permit laser beams 151A aligned with such openings to pass through stage block 152d. In some examples, such openings can be vertically aligned with interconnects 121, 131, 141 or with semiconductor devices 10, 20, 30 over substrate 11. In some examples, the opaque material is configured to be vertically aligned with portions of the first substrate that are misaligned with interconnects 121, 131, 141 or with semiconductor devices 10, 20, 30.

Such aligned laser beams 151A will cause heating and bonding of interconnects 121, 131, 141, as described with respect to the laser beams 151A that pass through stage block 152a in FIG. 6A. Laser beams 151A that are misaligned with such openings will instead be obstructed from passing through stage block 152d by the opaque material of opaque portion 152z.

As shown, laser beams 151A are irradiated from laser source 151 towards stage block 152d, and such laser beams 151A can pass through transparent material portion 152x of stage block 152d. Laser beams 151A aligned with the openings defined by the grating of opaque portion 152z can pass through stage block 152d to reach substrate 11 and cause heating of interconnects 121, 131, 141 for bonding. Laser beams 151A misaligned with the openings of the grating of opaque portion 152z will be substantially blocked from passing through stage block 152d. Interconnects 121, 131, 141 can be heated until bonded with conductive structure 112 of substrate 11.

The grating of opaque portion 152z can be configured such that areas of substrate 11 that need to be exposed for heating of interconnects 121, 131, 141 by laser beams 151A through stage block 152d are aligned with the pattern of openings. Other areas of substrate 11 that need not be exposed for bonding can be aligned with the opaque material of opaque portion 152z, or misaligned with the pattern of openings, to be blocked or shielded from laser beams 151A. Such features can limit unnecessary heat exposure of shielded areas of substrate 11 to restrict undue thermal expansion or warpage.

In some examples, the grating of opaque portion 152z can be configured such that the pattern of openings exposes portions of substrate 11 where semiconductor devices 10, 20, 30 are located, while other portions of substrate 11 outside the periphery of semiconductor devices 10, 20, 30 remain shielded by the material of opaque portion 152z.

In some examples, the grating of opaque portion 152z can be configured such that the pattern of openings exposes portions of substrate 11 where interconnects 121, 131, 141 are located, while other portions of substrate 11 outside the periphery of interconnects 121, 131, 141 remain shielded by the material of opaque portion 152z. For instance, as seen with respect to semiconductor device 20, the grating is configured such that opaque portion 152z (a) exposes portions of substrate 11 under semiconductor devices 12,13 within the periphery of interconnects 121,131, and (b) shields portions of substrate 11 under semiconductor devices 12,13 outside the periphery of interconnects 121,131.

There can be examples where a thickness of transparent portion 152x can be greater than the thickness of opaque portion 152z. For instance, transparent portion 152x can range in thickness from about 1 mm to about 300 mm, and opaque portion 152z can range in thickness from about 100 μm to about 100 mm. In some examples, opaque portion 152z can comprise one or more patterned plating layers that cover transparent portion 152x.

Interconnects 121, 131, 141 of can be heated until bonded with conductive structure 112 of substrate 11. Heat and time parameters can be properly controlled to minimize bonding time for fast throughput while avoiding exposure to higher temperatures to minimize undue thermal expansion or warpage of substrate 11. In some examples, laser beams 151A can be irradiated for about 2000 ms or less, or about 1000 ms or less, to cause proper heating and bonding of interconnects 121,131,141 with substrate 11. In some examples, heat caused by laser beams 151A on interconnects 121, 131, 141 or on substrate 11 can be controlled to remain under about 300° C. or 350° C., such as in the range from about 150° C. to about 350° C., or from about 230° C. to about 280° C.

In some examples, LAB tool 15 can comprise laser source 151U that can be similar to laser source 151 but can be configured to emit laser beams 151B towards a top side of semiconductor devices 10, 20, 30 or a top side of stage block 152a. Laser beams 151B can be similar to laser beams 151A, and can induce heating of interconnects 121, 131, 141 from the top of their respective semiconductor devices 10, 20, 30 to assist in bonding interconnects 121,131,141 to substrate 11.

As shown for FIGS. 6A-6D, LAB tool 15 can be provided along with compression tool 65 as part of hybrid bonder tool 60. Hybrid bonder tool 60 can comprise or can be similar to hybrid bonder tool 40 in some implementations, such as described with respect to FIG. 2B or FIG. 5. For instance, compression tool 65 can comprise or can be similar to TCB tool 35. Compression tool 65 can comprise plate 651 that can be similar to plate 351 or can provide one or more of compression, heat, or vibration to semiconductor device 30. In some examples, plate 651 of compression tool 65 can serve as a weight plate that provides compression on the top of semiconductor device 30, such as on top of semiconductor component 12 or 13, without also providing heat or vibration. In some examples, the inherent weight of plate 651 can provide the compression on the top of semiconductor device 30 without any additional force added to push plate 651 onto semiconductor device 30. The compression imparted by plate 651 at the top side of semiconductor device 30 can prevent or restrict undue warpage of semiconductor device 30, semiconductor component 12,13, or substrate 11 during bonding.

In some implementations, laser source 151U can be used along with compression tool 65 during bonding. For instance, features, characteristics, or materials of plate 651 of compression tool 65 can be similar to those described with respect to stage block 152a, 152b, 152c, or 152d in terms of transmittance, such that laser beams 151B can induce, through compression tool 65, bonding of semiconductor device 30 with substrate 11.

For example, as shown in FIG. 6A, plate 651 can be transparent or comprise a transparent material, similar to stage block 152a. Laser beams 151B from laser source 151U can pass through plate 651 and reach semiconductor device 30 or semiconductor components 12,13 to induce heat for bonding interconnects 121,131, similar to as described with respect to stage block 152a and laser beams 151A.

As another example, as shown in FIG. 6B, plate 651 can be opaque or comprise an opaque material, similar to stage block 152b. Laser beams 151B from laser source 151U can be obstructed or blocked by plate 651, but can heat plate 651 to induce transfer of heat for bonding interconnects 121,131, similar to as described with respect to stage block 152b and laser beams 151A.

As another example, as shown in FIG. 6C, plate 651 can comprise a combination or stack of transparent and opaque materials or layers, similar to stage block 152c. Laser beams 151B from laser source 151U can pass through the transparent material of plate 651 and reach the opaque material of plate 651, where they can be blocked but can heat plate 651 to induce transfer of heat for bonding interconnects 121,131, similar to as described with respect to stage block 152c and laser beams 151A.

As another example, as shown in FIG. 6D, plate 651 can comprise a combination or stack of transparent and opaque materials or layers that define a grating with transparent and opaque portions, similar to stage block 152d. A portion of laser beams 151B from laser source 151U can be blocked by the opaque material of the grating of plate 651. But a portion of laser beams 151B from laser source 151U can pass through the transparent material and the pattern of openings in the grating of plate 651, reaching the top of semiconductor device 30 or semiconductor components 12,13 to induce transfer of heat for bonding interconnects 121,131, similar to as described with respect to stage block 152d and laser beams 151A.

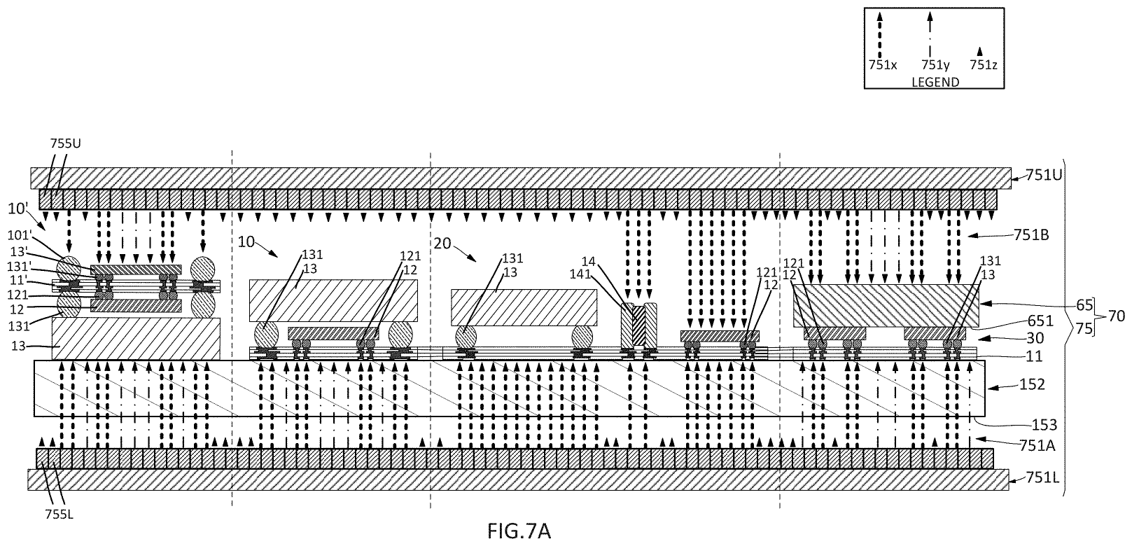

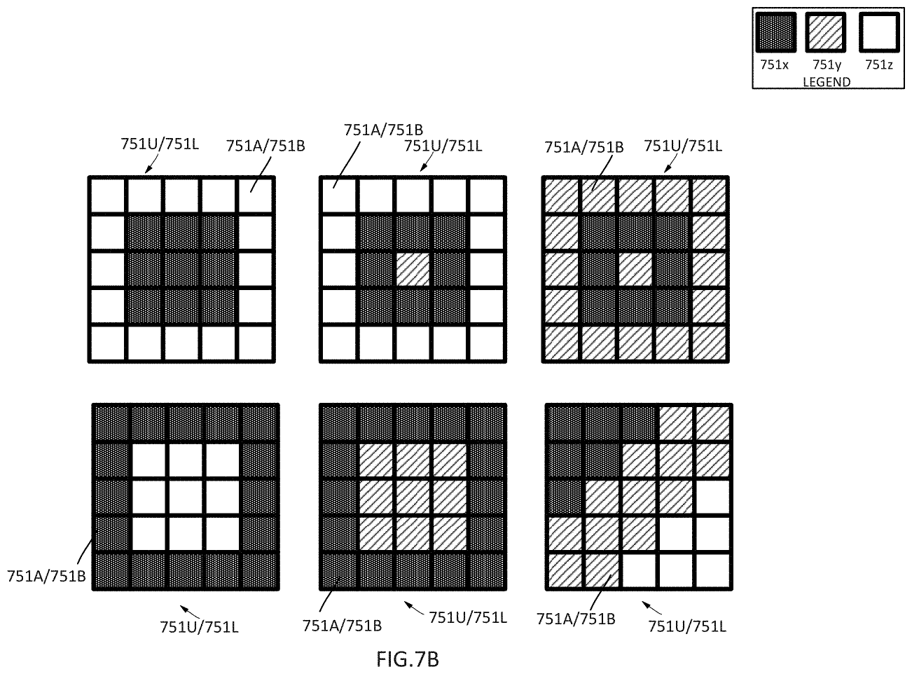

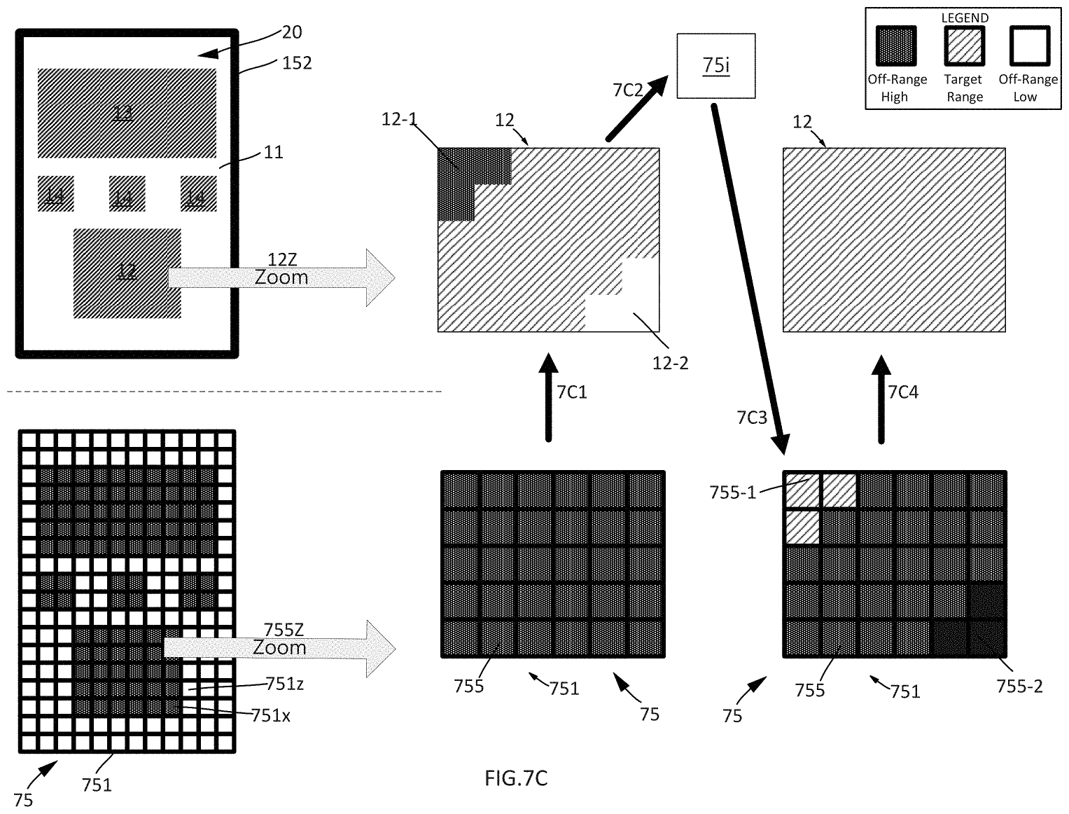

FIG. 7A shows a cross-sectional view of a bonding stage for bonding interconnects of semiconductor devices using LAB tool 75. LAB tool 75 can comprise laser source 751L configured to emit laser beams 751A, or laser source 751U configured to emit laser beams 751B. FIG. 7B shows plan views for different exemplary operating conditions of LAB tool 75 with laser beams 751A of laser source 751L or with laser beams 751B of laser source 751U. Lab bonding tool 75 is shown in FIG. 7A bonding interconnects of semiconductor devices 10′, 10, 20, 30 to respective substrates 11.

Semiconductor device 10′ is shown positioned on stage block 152, and can be similar to semiconductor device 10, 20, or 30 or variations. Semiconductor device 10′ can comprise electronic component 12 or 13 at a first side of substrate 11′, and can comprise interconnects 101′ or electronic component 13′ at a second side of substrate 11′. For instance, in some examples semiconductor device 10′ can lack electronic component 13′ at the second side of substrate 11′, or can lack electronic component 13 at the first side of substrate 11′ such that electronic component 12 is attached to stage block 152. In some examples interconnects 121, 131, 131′, or 141 can be concurrently bonded to respective sides of substrate 11′ by laser beams 751A or 751B of laser sources 751L or 751U. In some examples, interconnects 121 or 131 of electronic components 12 or 13 can be pre-bonded to the first side of substrate 11′, such by any of the first LAB bonding or hybrid bonding processes or tools described here, and then semiconductor device 10′ can be inverted and positioned on stage block 152 such that the second side of substrate 11′ faces towards laser source 751U of LAB tool 75 as shown in FIG. 7A for bonding of interconnects 101′ or 131′ by laser beams 751B.

LAB tool 75 can be similar to LAB tool 15, and can comprise laser source 751L aimed towards stage block 152. Stage block 152 can comprise any of one or more variations, including but not limited those described for stage block 152a, 152b, 152c, 152d with respect to FIG. 6A-6D. Laser source 751L can be similar to laser source 151, and can comprise a laser emitter array of laser emitters 755L. In some examples, laser source 751L can be referred as a laser emitter array, a laser emitter panel, or a laser diode panel.

Laser emitters 755L can individually emit respective laser beams 751A, which can be similar to laser beams 151A. Laser emitters 755L and respective laser beams 751A can be individually aligned vertically with a portion of a target, such as a portion of stage block 152 or a portion of semiconductor devices 10, 10′, 20, 30. In some examples, laser beams 751A emitted by laser source 751L can leave respective laser emitters 755L and proceed towards their respective targets individually. In some examples, laser source 751L need not rely on a filter, collimator, or lens for grouping, aiming, or directing a group of laser beams 751A. Laser source 751L can comprise an area large enough to concurrently process many substrates such as RDL substrates, pre-formed substrates, or wafers. In some examples, the length and width of laser source 751L can be at least about 300 mm×300 mm. For instance, the length and width of laser source 751L can be at least about 600 mm×600 mm.

In some examples, an individual laser emitter 755L can comprise a laser diode, such as an indium phosphide (InP), gallium nitride (GaN), zinc selenide (ZnSe), aluminium gallium arsenide (AlGaAs), indium gallium nitride (InGaN), or zinc oxide (ZnO) diode. There can be examples where an individual laser emitter 755L can comprise more than one laser diode. In some examples, an individual laser emitter 755L can comprise a length or a width of about 100 μm to about 2 mm. In some examples, the target area for the individual laser emitter can comprise a length or a width of about 100 μm to about 2 mm. In some examples, an individual laser emitter 755L can emit a laser beam 751A with power of about 10 milliwatts to about 2 Watts. In some examples, an individual laser emitter 755L can emit a laser beam 751A with wavelength of about 600 μm to about 2,000 μm.

As seen in FIGS. 7A and 7B, LAB tool 75 can control laser source 751L such that different laser emitters 755L can selectively emit respective laser beams 751A at different power levels towards different target areas. For instance, lab tool 75 can configure different individual laser emitters 755L to emit respective laser beams 751A at different laser power levels, such as high-power beam 751x, mid-power beam 751y (of lower power than high-power beam 751x), or low-power beam 751y (of lower power than high-power beam 751x or mid-power beam 751y). In some examples, such laser configurations can achieve different, adjustable, or varying power or temperature gradients across the target. In some examples, one or more laser beams 751A emitted as a low-power beams 751z can correspond to an unpowered or “off” state.

In some examples or areas, LAB tool 75 can control laser source 751L such that laser emitters 755L that are vertically aligned within the peripheries of interconnects 121, 131, 141 emit respective laser beams 751A as high-power beams 751x to heat and bond interconnects 121, 131, 141 to substrate 11.

In some examples or areas, such as seen with respect to semiconductor device 20, LAB tool 75 can control laser source 751L such that laser emitters 755L that are vertically aligned within the peripheries of electronic components 12, 13, 14 emit respective laser beams 751A as high-power beams 751x to bond electronic components 12, 13, 14 to substrate 11.

In some examples, LAB tool 75 can control laser source 751L such that laser emitters 755L that are vertically aligned with areas outside the peripheries of interconnects 121, 131, 141 emit respective laser beams 751A as mid-power beams 751y or low-power beams 751z.

For instance in FIG. 7A, with respect to semiconductor device 10, laser emitters 755L that are vertically aligned with electronic components 12,13 and outside the peripheries of interconnects 121,131 emit respective laser beams 751A as mid-power beams 751y.

For instance in FIG. 7A, with respect to semiconductor device 30, laser emitters 755L that are vertically aligned with electronic components 12,13 and outside the peripheries of interconnects 121,131 emit respective laser beams 751A as low-power beams 751z.

In some examples, such as seen with respect to semiconductor device 20, LAB tool 75 can control laser source 751L such that laser emitters 755L that are vertically aligned with areas between the peripheries of electronic components 12,13,14 emit respective laser beams 751A as low-power beams 751z.

In some examples, such as seen with respect to semiconductor device 30, LAB tool 75 can control laser source 751L such that laser emitters 755L that are vertically aligned with areas between the peripheries of electronic components 12,13 emit respective laser beams 751A as mid-power beams 751y.

In some examples or areas, LAB tool 75 can control laser source 751L such that laser emitters 755L that are vertically aligned with border regions between semiconductor devices 10, 10′, 20, 30 emit respective laser beams 751A as low-power beams 751z.

In some examples, LAB tool 75 can comprise laser source 751U located over stage block 152. In some examples, laser source 751U can be similar to laser source 151 or 151U. In some examples, laser source 751U can be similar to laser source 751L, and can comprise a laser emitter array of laser emitters 755U that can be similar to laser emitters 755L. There can be implementations where LAB tool 75 can comprise laser source 751U without laser source 751L, or can comprise laser source 751L without laser source 751U.

Laser emitters 755U can individually emit respective laser beams 751B, which can be similar to laser beams 751A. Laser emitters 755U and respective laser beams 751B can be individually aligned vertically with a portion of a target, such as a portion of stage block 152 or a portion of semiconductor devices 10, 10′, 20, 30. In some examples, laser beams 751B emitted by laser source 751U can leave respective laser emitters 755U and proceed towards their respective targets individually. In some examples, laser source 751U need not rely on a filter, collimator, or lens for grouping, aiming, or directing a group of laser beams 751B.

Upper laser emitters 755U of upper laser source 751U can be aimed towards the top side of stage block 152, and lower laser emitters 755L of lower laser source 751L can be aimed towards the bottom side of stage block 152. LAB tool 75 can control laser source 751U and laser source 751L to concurrently emit or adjust laser beams 751A or 751B during the bonding of substrate 11 with semiconductor devices 10, 10′, 20, 30 or with interconnects 121, 131, 101′, or 141.

As seen in FIGS. 7A and 7B, LAB tool 75 can control laser source 751U such that different laser emitters 755U can selectively emit respective laser beams 751B at different power levels towards different target areas. For instance, LAB tool 75 can configure different individual laser emitters 755U to emit respective laser beams 751B at different laser power levels, such as high-power beam 751x, mid-power beam 751y (of lower power than high-power beam 751x), or low-power beam 751y (of lower power than high-power beam 751x or mid-power beam 751y). In some examples, such laser configurations can achieve different, adjustable, or varying power or temperature gradients across the target. In some examples, one or more laser beams 751B emitted as a low-power beams 751z can correspond to an unpowered or “off” state.

In some examples or areas, LAB tool 75 can control laser source 751U such that laser emitters 755U that are vertically aligned within the peripheries of interconnects 121, 131, 101′, 141 emit respective laser beams 751B as high-power beams 751x to heat and bond respective target interconnects 121, 131, 101′, 141 to substrate 11.

In some examples or areas, such as seen with respect to semiconductor device 20, LAB tool 75 can control laser source 751U such that laser emitters 755U that are vertically aligned within the peripheries of target electronic components 12, 14 emit respective laser beams 751B as high-power beams 751x to bond electronic components 12, 14 to substrate 11. In some cases, not all components of a device need be targeted. For example, as also seen with respect to semiconductor device 20, LAB tool 75 can control laser source 751U such that laser emitters 755U that are vertically aligned within the periphery of electronic component 13 emit respective laser beams 751B as low-power beam 751z, or mid-power beam 751y. Such adjustment can be done, for instance, when electronic component 13 comprises a material that could be sensitive to laser beams 751B, or a material that could block, reflect, or hinder passage of laser beams 751B. In some examples, such materials can comprise mold compound, or a metal such as for heat dissipation or for electro-magnetic interference (EMI) shielding.

In some examples, LAB tool 75 can control laser source 751U such that laser emitters 755U that are vertically aligned with areas outside the peripheries of interconnects 121, 131, 101′, 141 emit respective laser beams 751A as mid-power beams 751y or low-power beams 751z.

As shown in FIG. 7A, compression tool 65 can be provided along with LAB tool 75 as part of hybrid bonder tool 70. Compression tool 65 can be as described with respect to FIG. 6.

Compression tool 65 can comprise or can be similar to TCB tool 35, where plate 651 that can be similar to plate 351 or can provide one or more of compression, heat, or vibration to semiconductor device 30 during bonding. In some examples, plate 651 of compression tool 65 can serve as a weight plate that provides compression on the top of semiconductor device 30, such as on top of semiconductor component 12 or 13, without also providing heat or vibration. In some examples, the inherent weight of plate 651 can provide the compression on the top of semiconductor device 30 without any additional force added to push plate 651 onto semiconductor device 30. The compression imparted by plate 651 at the top side of semiconductor device 30 can prevent or restrict undue warpage of semiconductor device 30, semiconductor component 12,13, or substrate 11 during bonding.

In some implementations, laser source 751U can be used along with compression tool 65 during bonding. Features, characteristics, or materials of plate 651 of compression tool 65 can be similar to those already described with respect to any of FIGS. 6A-6D, such that laser beams 751B can induce, through compression tool 65, bonding of semiconductor device 30 with substrate 11.

As an example, similar to as described with respect to FIG. 6A, plate 651 can be transparent or comprise a transparent material. Laser beams 751B from laser source 751U, such as high-power beams 751x or mid-power beams 751y, can pass through plate 651 and reach respective target areas of semiconductor device 30 or semiconductor components 12,13 to induce heat for bonding interconnects 121,131.

As another example, similar to as described with respect to FIG. 6B, plate 651 can be opaque or comprise an opaque material. Laser beams 751B from laser source 751U, such as high-power beams 751x or mid-power beams 751y, can be obstructed or blocked by plate 651, but can heat plate 651 to induce transfer of heat for bonding interconnects 121,131.

As another example, similar to as described with respect to FIG. 6C, plate 651 can comprise a combination or stack of transparent and opaque materials or layers. Laser beams 751B from laser source 751U, such as high-power beams 751x or mid-power beams 751y, can pass through the transparent material of plate 651 and reach the opaque material of plate 651, where they can be blocked but can heat plate 651 to induce transfer of heat for bonding interconnects 121,131.

As another example, similar to as described with respect to FIG. 6D, plate 651 can comprise a combination or stack of transparent and opaque materials or layers that define a grating with transparent and opaque portions. A portion of laser beams 751B from laser source 751U can be blocked by the opaque material of the grating of plate 651. But a portion of laser beams 751B from laser source 751U, such as high-power beams 751x or mid-power beams 751y, can pass through the transparent material and the pattern of openings in the grating of plate 651, reaching the top of semiconductor device 30 or semiconductor components 12,13 to induce transfer of heat for bonding interconnects 121,131.

FIG. 7C shows respective plan views of semiconductor device 20 (comprising electronic components 12,13,14 on substrate 11), and laser source 152 (comprising respective laser emitters 755 vertically aligned with semiconductor device 20), where such plan views correspond to respective portions of the side view of FIG. 7A. Laser source 751 can correspond to either of laser source 751L or laser source 751U. Laser emitters 755 can correspond to either of laser emitters 755L or 755U.

In the present example, LAB tool 75 controls laser emitters 755 that are vertically aligned with electronic components 12,13,14 to emit laser beams (such as laser beams 751A or 751B from FIG. 7A) as high-power beams 751x to cause bonding of electronic components 12,13,14 with substrate 11. In the present example, LAB tool 75 also controls laser emitters 755 that are not vertically aligned with electronic components 12,13,14 to emit laser beams (such as laser beams 751A or 751B from FIG. 7A) as low-power beams 751z.

In some examples, LAB tool 75 can comprise bonding monitor 75i that measures temperatures of multiple areas of semiconductor device 20 in real-time during bonding. Bonding monitor 75i can comprise, for instance, an optical infrared imager or monitor. Bonding monitor 75i can be configured to determine whether target temperatures are being achieved by the laser beams of laser emitter 755 for each of such multiple areas of semiconductor device 20. Such monitoring can be useful for confirming that proper temperatures for interconnect bonding are being achieved, and for guarding against temperatures that could cause undue heating, thermal expansion, warpage, or damage to substrate 11 or electronic components 12,13,14. If bonding monitor 75i determines that some target areas of semiconductor device 20 measure outside their target temperature range (“off-range”) during bonding, LAB tool 75 can react in real-time and selectively control individual laser emitters 755 aligned with such off-range areas to increase or decrease the power of the laser beams emitted towards such off-range areas to bring them within their target temperature range.

An example with steps 7C1-7C4 can illustrate such operation. As seen in FIG. 7C, zoomed-in portion 12Z of electronic component 12, and zoomed-in portion 755Z of laser source 751 are shown. Zoomed-in portion 755Z presents laser emitters 755 that are vertically aligned with electronic component 12.

In step 7C1, as seen in zoomed portion 755Z, laser emitters 755 emit laser beams at initial or baseline power towards the area corresponding to electronic component 12, and as seen in zoomed portion 12Z, heat is correspondingly generated by such laser beams in electronic component 12.

In step 7C2, bonding monitor 75i, which monitors the temperature of the multiple areas of electronic component 12 during bonding, identifies off-range area 12-1 at higher temperature than its target temperature range, and identifies off-range area 12-2 at lower temperature than its target temperature range.

In step 7C3, LAB tool 75, based on the monitoring information from bonding monitor 75i, selectively controls laser emitters 755-1 and laser emitters 755-2 to adjust the power of their respective laser beams. Laser emitters 755-1 are vertically aligned with off-range area 12-1 of electronic component 12, and laser emitters 755-2 are vertically aligned with off-range area 12-2 of electronic component 12. To counteract the measured high temperature at off-range area 12-1 of electronic component 12, LAB tool 75 can selectively control laser emitters 755-1 to decrease the power of their laser beams. To counteract the measured low temperature at off-range area 12-2 of electronic component 12, LAB tool 75 can selectively control laser emitters 755-2 to increase the power of their laser beams.

In step 7C4, off-range areas 12-1 and 12-2 of electronic component 12 reach their target temperature as a result of the laser beam adjustments of corresponding laser emitters 755-1 and 755-2. Bonding monitor 75i can keep monitoring the multiple areas of electronic component 12, such that LAB tool 75 can keep selectively controlling the power of respective laser emitters 755 as needed to maintain the multiple areas of electronic component 12 within their target temperature range during bonding.

The present disclosure includes reference to certain examples. It will be understood by those skilled in the art, however, that various changes may be made, and equivalents may be substituted without departing from the scope of the disclosure. It is also understood by those skilled in the art that, for simplicity and clarity of the drawings, several variations or options can be inherently disclosed by the figures supported by the description. For example, any of semiconductor devices 10, 10′, 20, 30 can comprise a dielectric, such as underfill or an encapsulant like mold compound, around any of respective interconnects 121, 131, 141, 101′ to further secure them to respective substrate 11, 11′. As another example, any of any of semiconductor devices 10, 10′, 20, or 30 can comprise an encapsulant, such as mold compound, that covers one or more sides of substrate 11, 11′ and one or more sides of elements 12, 13, 13′, 14, 101′. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. A system, comprising:
a laser assisted bonding (LAB) tool, comprising:
a stage block; and
a laser source facing the stage block;
wherein:
the stage block is configured to support a first substrate and a first electronic component coupled with the first substrate, the first electronic component comprising a first interconnect; and
the laser source is configured to emit a first laser towards the stage block to induce a first heat on the first interconnect to bond the first interconnect with the first substrate.

2. The system of claim 1, wherein:
the first substrate and the first electronic component are at a top side of the stage block; and
the laser source emits the first laser towards the bottom side of the stage block.

3. The system of claim 1, wherein:
the first electronic component is at a top side of the stage block;
the substrate is at a top side of the first electronic component; and
the laser source emits the first laser towards the top side of the stage block;

4. The system of claim 1, wherein:
the stage block comprises a transparent material portion that permits the first laser to pass through and reach the first substrate.

5. The system of claim 1, wherein:
the stage block comprises an opaque material portion that blocks the first laser from passing through and reaching the first substrate.

6. The system of claim 1, wherein:
the stage block comprises:
an opaque material portion that blocks the first laser from passing through and reaching the first substrate; and
a transparent material portion that permits the first laser to pass through and reach the opaque material.

7. The system of claim 1, wherein:
the stage block comprises an opaque material portion;
the opaque material portion comprises an opaque material and a grating defining a pattern of openings though the opaque material;
the opaque material blocks the first laser from passing through and reaching the first substrate; and
the grating permits the first laser to pass through the pattern of openings and reach the first substrate.

8. The system of claim 7, wherein:
the stage block comprises a transparent material portion that permits the first laser to pass through and reach the first substrate through the grating of the opaque material portion.

9. The system of claim 7, wherein:
the openings of the grating are configured to be vertically aligned with interconnects of the first electronic component over the first substrate.

10. The system of claim 7, wherein:
the opaque material is configured to be vertically aligned with portions of the first substrate that are misaligned with interconnects of the first electronic component.

11. The system of claim 1, wherein:
the laser source comprises an array of laser emitters comprising:
a first laser emitter configured to emit the first laser as a vertical first laser beam towards a first target area; and
a second laser emitter configured to emit a vertical second laser beam towards a second target area that does not overlap the first target area.

12. The system of claim 11, wherein:
the LAB tool is configured to:
emit the first laser beam from the first laser emitter as a high-power beam; and
emit the second laser beam from the second laser emitter as a low-power beam.

13. The system of claim 11, wherein:
the LAB tool is configured to:
emit the first laser beam from the first laser emitter as a high-power beam when the first laser emitter is vertically aligned within a periphery of the first interconnect of the first electronic component; and
emit the second laser beam from the second laser emitter as a low-power beam when the second laser emitter is vertically aligned outside the periphery of the first interconnect of the first electronic component.

14. The system of claim 11, wherein:
the LAB tool is configured to:
emit the first laser beam from the first laser emitter as a high-power beam when the first laser emitter is vertically aligned within a periphery of the first electronic component; and
emit the second laser beam from the second laser emitter as a low-power beam when the second laser emitter is vertically aligned outside the periphery of the first electronic component.

15. The system of claim 11, wherein:
the LAB tool is configured to:
emit the first laser beam from the first laser emitter as a high-power beam when the first laser emitter is vertically aligned within a periphery of the first electronic component; and
emit the second laser beam from the second laser emitter as a low-power beam when the second laser emitter is vertically aligned within the periphery of the first electronic component but outside the periphery of the first interconnect of the first electronic component.

16. The system of claim 11, wherein:
the stage block is configured to support a second electronic component coupled to the first substrate and adjacent to the first electronic component, the second electronic component comprising a second interconnect;
the array of laser emitters comprises a third laser emitter configured to emit a vertical third laser beam towards a third target area; and
the LAB tool is configured to:
emit the first laser beam from the first laser emitter as a high-power beam vertically aligned within a periphery of the first electronic component;
emit the second laser beam from the second laser emitter as a high-power beam vertically aligned within a periphery of the second electronic component; and
emit the third laser beam from the third laser emitter as a low-power beam when the third laser emitter is vertically aligned within a border region between the first and second electronic components.

17. The system of claim 11, wherein:
the array of laser emitters comprises:
a third laser emitter configured to emit a vertical third laser beam towards a third target area; and
a fourth laser emitter configured to emit a vertical fourth laser beam towards a fourth target area;
the first electronic component comprises a second interconnect; and
the LAB tool is configured to:
emit the first laser beam from the first laser emitter as a high-power beam vertically aligned within a periphery of the first interconnect;
emit the second laser beam from the second laser emitter as a high-power beam vertically aligned within a periphery of the second interconnect;
emit the third laser beam from the third laser emitter as a mid-power beam vertically aligned within a periphery of the first electronic component but outside the peripheries of the first and second interconnects; and
emit the fourth laser beam from the fourth laser emitter as a low-power beam vertically aligned outside the periphery of the first electronic component.

18. The system of claim 11, wherein:
the LAB tool is configured to:
monitor temperatures of multiple target areas of the first electronic component, the multiple areas comprising:
the first target area of the first laser beam; and
the second target area of the second laser;
and in real-time:
adjust power of the first laser beam to bring a first off-range temperature of the first target area of the first electronic component to within a target temperature range; and
adjust power of the second laser beam to bring a second off-range temperature of the second target area of the first electronic component to within the target temperature range.

19. The system of claim 11, wherein:
the LAB tool is configured to:
increase in real-time a power of the first laser beam to bring a first off-range temperature of a first target area from lower than a target temperature range to within the target temperature range; and
decrease in real-time a power of the second laser beam to bring a second off-range temperature of a second target area from higher than the target temperature range to within the target temperature range.

20. A semiconductor device comprising:
a substrate comprising a substrate top side and a substrate bottom side; and
a first electronic component comprising a first interconnect bonded to the substrate top side by a first laser beam emitted towards the substrate bottom side.
